(19) United States
(12) Patent Application Publication
(10) Pub. No.: US 2024/0419876 A1
(43) Pub. Date: Dec. 19, 2024

(54) Hardware-Software Co-Design to Accelerate Garbled Circuits

(71) Applicant: New York University

(72) Inventors: Brandon Reagen, New York, NY (US); Jianqiao Mo, Brooklyn, NY (US); Jayanth Gopinath, San Jose, CA (US)

(21) Appl. No.: 18/745,706

(22) Filed: Jun. 17, 2024

Related U.S. Application Data
(60) Provisional application No. 63/521,675, filed on Jun. 17, 2023.

(51) Int. Cl. G06F 30/32; G06F 9/38; G06F 12/02

(52) U.S. Cl. CPC G06F 30/32; G06F 9/3836; G06F 12/0223

(57) ABSTRACT

A novel garbled circuit (GC) accelerator and compiler, named HAAC, mitigates performance overheads and makes privacy-preserving computation more practical. HAAC is a hardware-software co-design. GCs are exemplars of co-design as programs are completely known at compile time because all dependence, memory accesses, and control flow are fixed. The compiler can leverage its program understanding to realize hardware's performance potential by generating effective instruction schedules, data layouts, and managing off-chip events. Arbitrary GC programs may be expressed as streams, which simplifies hardware, and the development of an adaptive, on-chip scratchpad that tracks program execution to capture data reuse despite the lack of a regular access pattern or requiring tagging.

### § 2. RELATED APPLICATIONS

The present application claims priority to U.S. Provisional Application Ser. No. 63/521,675 (referred to as “the '675 provisional” and incorporated herein by referenced, titled “HAAC: A Hardware-Software Co-Design to Accelerate Garbled Circuits”, filed on Jun. 17, 2023, and listing Brandon Reagen, Jianqiao Mo, and Jayanth Gopinath as the inventors. The present application is not limited by any specific requirements discussed in the '675 provisional.

### § 1. FEDERAL FUNDING

This invention was made with government support under HR0011-18-3-0004 awarded by the Defense Advanced Research Projects Agency. The government has certain rights in the invention.

### § 3. BACKGROUND OF THE INVENTION

### § 3.1 Field of the Invention

The present application concerns managing a memory for storing operands input to and output from, hardware operators, such as, for example, in the context of privacy-preserving computing.

### § 3.2 Background Information

Privacy and security continue to increase in importance and demand new computational techniques to provide strong data protection guarantees to users. This has given rise to a new paradigm of computing. Privacy-preserving computation (PPC) can provide users two major advantages: confidentiality; and control. Confidential computing enables computation on encrypted data, guaranteeing that service providers cannot view users' sensitive, personal data while still providing them access to high-quality services. Some techniques (namely secure multi-party computation) further allow users to control how their data is used, dictating which functions their data is computed with. While promising, the ubiquitous deployment of all cryptographically strong PPC techniques are limited by extreme runtime slowdown, which today are far too high for most applications. Thus, novel hardware solutions are needed to mitigate overheads and usher in a new era of private computing.

Although a variety of PPC techniques exist, the present description focuses on garbled circuits (GCs). Each PPC technique has its strengths and weaknesses, and these are discussed in detail in § 3.2.1, below. For now, note that the future likely contains a mixture of all PPC techniques, as their strengths can be combined to overcome their individual limitations. The intent of the present description is not to argue whether GCs or, for example, homomorphic encryption, is superior to other PPC techniques, but rather to show how the performance overheads of GCs can largely be overcome with hardware acceleration.

### § 3.2.1 Overview of PPC Techniques

This section includes an overview of PPC techniques, their tradeoffs, and a GC primer. The intent is to provide the reader with enough information to understand the contributions of the present disclosure. It is not a complete review, and those interested in further detail should read related materials (See, e.g., the documents: S. Even, O. Goldreich, and A. Lempel, “A randomized protocol for signing contracts,” Communications of the ACM, vol. 28, no. 6, pp. 637-647, 1985 (incorporated herein by reference).); V. Kolesnikov and T. Schneider, “Improved garbled circuit: Free xor gates and applications,” vol. 7, 07 2008, pp. 486-498 (incorporated herein by reference).); X. Wang, A. J. Malozemoff, and J. Katz, “EMP-toolkit: Efficient MultiParty computation toolkit,” https://github.com/emp-toolkit, 2016 (incorporated herein by reference); A. C.-C. Yao, “How to generate and exchange secrets,” in 27th Annual Symposium on Foundations of Computer Science (sfcs 1986), 1986, pp. 162-167 (incorporated herein by reference); and S. Zahur, M. Rosulek, and D. Evans, “Two halves make a whole,” in Advances in Cryptology—EUROCRYPT 2015, E. Oswald and M. Fischlin, Eds. Berlin, Heidelberg: Springer Berlin Heidelberg, 2015, pp. 220-250 (incorporated herein by reference).).

### § 3.2.1.1 Techniques for PPC

The present description classifies cryptographic privacy-preserving techniques into three categories: homomorphic encryption (HE), secret sharing (SS), and garbled circuits (GCs). Each technique has strengths and weaknesses, briefly recapped below. A common drawback of all PPC techniques is computational overhead.

### § 3.2.1.1.1 Homomorphic Encryption

Homomorphic encryption works like standard encryption with the added benefit that functions can be computed directly on encrypted data, providing end-to-end confidentiality. HE fits the mold of today's client-cloud service model, requiring that only one party, typically the cloud, be involved in the computation. The drawbacks of HE are limited functionality and the inability to control data usage. Integer (including fixed point). HE schemes (See, e.g., the documents: Z. Brakerski, C. Gentry, and V. Vaikuntanathan, “(leveled) fully homomorphic encryption without bootstrapping,” ACM Transactions on Computation Theory, 2014 (incorporated herein by reference); J. H. Cheon, A. Kim, M. Kim, and Y. Song, “Homomorphic encryption for arithmetic of approximate numbers,” in International conference on the theory and application of cryptology and information security, 2017 (incorporated herein by reference); and J. Fan and F. Vercauteren, “Somewhat practical fully homomorphic encryption,” Cryptology ePrint Arc hive, 2012 (incorporated herein by reference).) only provide functional support for addition and multiplication, limiting what can be computed. Binary schemes exist (e.g., TFHE (See, e.g., Chillotti, N. Gama, M. Georgieva, and M. Izabache ne, “The fast fully homomorphic encryption over the torus,” Journal of Cryptology, 2020 (incorporated herein by reference).)) that, like GCs, can compute arbitrary functions. However, these are far from practical as a single gate can take 75-600 milliseconds to process (See, e.g., the documents: H. Hsiao, V. Lee, B. Reagen, and A. Alaghi, “Homomorphically encrypted computation using stochastic encodings,” arXiv preprint arXiv:2203.02547, 2022 (incorporated herein by reference); and D. Micciancio and Y. Polyakov, “Bootstrapping in fhew-like cryptosystems,” in Proceedings of the 9th on Workshop on Encrypted Computing & Applied Homomorphic Cryptography, 2021, pp. 17-28 (incorporated herein by reference).). Integer HE slowdown is typically on the order of 5-6 orders of magnitude (See, e.g., the documents: A. Feldmann, N. Samardzic, A. Krastev, S. Devadas, R. Dreslinski, K. Eldefrawy, N. Genise, C. Peikert, and D. Sanchez, “F1: A fast and programmable accelerator for fully homomorphic encryption (extended version),” 2021 (incorporated herein by reference).); and B. Reagen, W. Choi, Y. Ko, V. Lee, G.-Y. Wei, H.-H. S. Lee, and D. Brooks, “Cheetah: Optimizing and accelerating homomorphic encryption for private inference,” 2020 (incorporated herein by reference).); most systems research has been focused here (See, e.g., the documents: A. Feldmann, N. Samardzic, A. Krastev, S. Devadas, R. Dreslinski, K. Eldefrawy, N. Genise, C. Peikert, and D. Sanchez, “F1: A fast and programmable accelerator for fully homomorphic encryption (extended version),” 2021 (incorporated herein by reference); S. Kim, J. Kim, M. Kim, W. Jung, M. Rhu, J. Kim, and J. H. Ahn, “Bts: An accelerator for bootstrappable fully homomorphic encryption,” 12 2021 (incorporated herein by reference); B. Reagen, W. Choi, Y. Ko, V. Lee, G.-Y. Wei, H.-H. S. Lee, and D. Brooks, “Cheetah: Optimizing and accelerating homomorphic encryption for private inference,” 2020 (incorporated herein by reference); M. S. Riazi, K. Laine, B. Pelton, and W. Dai, “Heax: An architecture for computing on encrypted data,” in Proceedings of the Twenty-Fifth International Conference on Architectural Support for Programming Languages and Operating Systems, 2020 (incorporated herein by reference); N. Samardzic, A. Feldmann, A. Krastev, N. Manohar, N. Genise, S. Devadas, K. Eldefrawy, C. Peikert, and D. Sanchez, “Craterlake: a hardware accelerator for efficient unbounded computation on encrypted data,” 06 2022, pp. 173-187 (incorporated herein by reference); and S. Sinha Roy, F. Turan, K. Jarvinen, F. Vercauteren, and I. Verbauwhede, “Fpga-based high-performance parallel architecture for homomorphic computing on encrypted data,” in 2019 IEEE International Symposium on High Performance Computer Architecture (HPCA), 2019, pp. 387-398 (incorporated herein by reference).).

### § 3.2.1.1.2 Secret-Sharing

Secret-sharing (SS) enables secure computation by splitting data into shares. Each party (e.g., a client and server) computes a function on their share and their respective results can be combined to reveal the function output. Since both parties must work together to correctly perform the computation, SS provides control over how data is used in addition to confidentiality. Another benefit of SS is that many of the costly operations can be moved offline. Recent research has shown these protocols work well for private neural inference (See, e.g., the documents: Z. Ghodsi, N. K. Jha, B. Reagen, and S. Garg, “Circa: Stochastic relus for private deep learning,” 2021 (incorporated herein by reference).); N. K. Jha, Z. Ghodsi, S. Garg, and B. Reagen, “Deepreduce: Relu reduction for fast private inference,” 2021 (incorporated herein by reference); and P. Mishra, R. Lehmkuhl, A. Srinivasan, W. Zheng, and R. A. Popa, “Delphi: A cryptographic inference service for neural networks,” in 29th USENIX Security Symposium (USENIX Security 20). USENIX Association, August 2020, pp. 2505-2522 (incorporated herein by reference).). SS, like HE, is limited in that it excels at addition and multiplication, typically relying on other PPCs for non-linear functions. It is common practice to pair SS with GCs in high-performance private neural inference protocols. Another major drawback is that SS requires HE in the offline phase, which introduces high overhead.

### § 3.2.1.1.3 Garbled Circuits

The strengths of GCs are that they support confidential computing, provide controls over how data is used, and can compute arbitrary functions. GCs security is not based on noise, which simplifies GC programming as the user does not have to manage noise like in HE. The drawbacks of GCs include high computational overheads and large data footprints due to the wires and tables. GCs also involve both parties to take part in the computation.

As just noted, GCs provide strong confidentiality guarantees and controls over how data is used. A salient feature of GCs is their support of arbitrary computation. GC programs constitute (secure) Boolean logic, implying any function can be implemented, including conditionals (many alternative PPC techniques restrict functional support, e.g., to addition and multiplication only). A notable recent application has been to execute non-linear layers in private neural inference (See, e.g., the documents: C. Juvekar, V. Vaikuntanathan, and A. Chandrakasan, “{GAZELLE}: A low latency framework for secure neural network inference,” in 27th USENIX Security Symposium (USENIX Security 18), 2018, pp. 1651-1669 (incorporated herein by reference); and P. Mishra, R. Lehmkuhl, A. Srinivasan, W. Zheng, and R. A. Popa, “Delphi: A cryptographic inference service for neural networks,” in 29th USENIX Security Symposium (USENIX Security 20). USENIX Association, August 2020, pp. 2505-2522 (incorporated herein by reference).).

Unfortunately, however, the potential of GCs is still unrealized as they incur very high performance overheads. For example, a 128-bit Advanced Encryption Standard (AES) computation is 90,000× slower when processed with garbled circuits software than the plaintext alternative. The overheads can be so high that recent work has identified GC execution as the primary bottleneck for private neural inference using hybrid protocols. (Hybrid protocols combine multiple PPCs. Many of the cited works combining homomorphic encryption and GCs.) (See, e.g., the documents: K. Garimella, Z. Ghodsi, N. K. Jha, S. Garg, and B. Reagen, “Characterizing and optimizing end-to-end systems for private inference,” 2022 (incorporated herein by reference); Z. Ghodsi, A. Veldanda, B. Reagen, and S. Garg, “Cryptonas: Private inference on a relu budget,” 2021 (incorporated herein by reference); J. Liu, M. Juuti, Y. Lu, and N. Asokan, “Oblivious neural network predictions via minionn transformations,” in Proceedings of the ACM SIGSAC Conference on Computer and Communications Security, 2017 (incorporated herein by reference); and P. Mishra, R. Lehmkuhl, A. Srinivasan, W. Zheng, and R. A. Popa, “Delphi: A cryptographic inference service for neural networks,” in 29th USENIX Security Symposium (USENIX Security 20). USENIX Association, August 2020, pp. 2505-2522 (incorporated herein by reference).).

Multiple factors contribute to GC's high overheads. First, processing each GC gate entails a significant amount of computation. The original (non-optimized) GC gate involves eight AES computations and many assorted 128-bit operations. (See, e.g., A. C.-C. Yao, “How to generate and exchange secrets,” in 27th Annual Symposium on Foundations of Computer Science (sfcs 1986), 1986, pp. 162-167 (incorporated herein by reference).). Second, executing a function with GCs requires a large number of gates to be processed, as it must be expressed as Boolean logic. For example, computing a private 128-bit AES requires processing 33616 gates. Third, there is a high ciphertext expansion factor in GCs, which is the ratio between plaintext and ciphertext data size. Each plaintext binary gate's inputs and output, called wires, is encrypted as a 128-bit ciphertext, causing a ciphertext expansion factor of 128x. Finally, each gate involves an additional constant, called a table. Algorithmic optimizations have demonstrated how tables can be eliminated for XOR gates and halved for AND gates. However, tables still put significant pressure on the memory system, as each Half-Gate (See, e.g., S. Zahur, M. Rosulek, and D. Evans, “Two halves make a whole,” in Advances in Cryptology—EUROCRYPT 2015, E. Oswald and M. Fischlin, Eds. Berlin, Heidelberg: Springer Berlin Heidelberg, 2015, pp. 220-250 (incorporated herein by reference).) AND's table is 32 Bytes and cannot be reused across gates.

Garbled circuits are a type of secure two party computation that constitute two phases: garbling; and evaluation. It allows two parties, Alice (the Garbler) and Bob (the Evaluator), to jointly compute y=ƒ(a, b) on secret inputs: a from Alice and b from Bob. During garbling, one party (Alice, the Garbler) generates “wire labels,” which serve as encrypted inputs. The parties engage in oblivious transfer (See, e.g., S. Even, O. Goldreich, and A. Lempel, “A randomized protocol for signing contracts,” Communications of the ACM, vol. 28, no. 6, pp. 637-647, 1985 (incorporated herein by reference).), a protocol which allows Bob to obtain his encrypted value of b without Alice learning anything about b. Alice also encrypts the truth table of each Boolean gate. This encrypted truth table is called a garbled table, or table, and is sent to Bob (the Evaluator). As functions are known before inputs, garbling can be done offline. During the evaluation phase an Evaluator takes encrypted wire labels and tables as input to compute Boolean gates securely. FIG. 1 shows an example of GC evaluation with the key terms (e.g., gates, wires, labels and tables). Gate outputs are also wire labels, and can serve as inputs to other gates or shared with the Garbler to reveal the output. Evaluation is done online as the computation is input dependent.

### § 3.2.1.1.3.1 Garbling

Garbled circuits work by encrypting truth table representations of gates. The first step is to convert a program f into a gate netlist, including all input/output wires. For each wire i, the Garbler will generate two random labels, Wiᵢ⁰ and Wᵢ¹, to represent the logical values 0 and 1, respectively. Next, each gate in the netlist will be encrypted. Encryption is done by applying AES to each row of the truth table; only binary gates are supported. Each truth table has four rows, two inputs and two possible labels per input. The Garbler encrypts the table using the two random labels as the keys. One example of the encrypted row r will be: Tableᵣ=Enc_{(W}_{^{A}}_{,W}_{_{B}}₎W_{C}, where wires A, B are two inputs and wire C is output.

### § 3.2.1.1.3.2 Evaluation

The evaluation phase uses the encrypted tables to evaluate secure inputs. To do this, the party holding the plaintext data converts it to binary, matches each input bit to each wire, and selects the wire label corresponding to 0 or 1 depending on the input. Label selection of the Evaluator's input is kept secure using oblivious transfer. (See, e.g., S. Even, O. Goldreich, and A. Lempel, “A randomized protocol for signing contracts,” Communications of the ACM, vol. 28, no. 6, pp. 637-647, 1985 (incorporated herein by reference).) Once all input labels are ready, the Evaluator decrypts each gate Dec_{(W}_{_{A}}_{,W}_{_{B}}₎Tableᵣ, and only one of the four rows will be decrypted correctly. The decrypted gate value is an encrypted wire label and used as input to the subsequent gates. Once the Evaluator finishes processing all gates they share the final output labels with the Garbler, and the Garbler will share the mapping of labels to plaintext binary values.

### § 3.2.1.1.3.3 Optimizations

Many optimizations have been made to significantly improve GC efficiency and performance. The most high-performance GC constructions implement AND and XOR gates, with AND being more expensive. HAAC leverages two widely used optimizations for improving the performance of XOR, namely (1) FreeXOR (See, e.g., V. Kolesnikov and T. Schneider, “Improved garbled circuit: Free xor gates and applications,” vol. 7, 07 2008, pp. 486-498 (incorporated herein by reference).) and (2) AND gate optimization using the Half-Gate technique (See, e.g., S. Zahur, M. Rosulek, and D. Evans, “Two halves make a whole,” in Advances in Cryptology—EUROCRYPT 2015, E. Oswald and M. Fischlin, Eds. Berlin, Heidelberg: Springer Berlin Heidelberg, 2015, pp. 220-250 (incorporated herein by reference).). These optimizations are described below as implemented by HAAC's gate engines consistent with the present description.

### § 3.2.1.1.3.3.1 FreeXOR Optimization

FreeXOR (See, e.g., V. Kolesnikov and T. Schneider, “Improved garbled circuit: Free xor gates and applications,” vol. 7, 07 2008, pp. 486-498 (incorporated herein by reference).) enables the computation of XOR gates using only wire labels by XORing them together. These gates are free as they require neither tables nor expensive AES/key expansion to evaluate. In FreeXOR, the Garbler generates a random (k−1)-bit value R, which is known only to itself. For each wire i, the Garbler generates the label Wᵢ⁰ to represent logical 0, and sets Wᵢ¹=Wᵢ⁰⊕(R∥1) for logical 1. Here (R∥1) is a k-bit value ending with 1. The Garbler also sets W_{C}^{o}=W_{A}⁰⊕W_{B}⁰. Following this convention, an output wire label C can be computed on input wires A and B as W_{C}=W_{A}⊕W_{B}.

### § 3.2.1.1.3.3.2 Half-Gate Optimization

The Half-Gate technique optimizes AND gates by halving the number of rows in the gate's table, and has even been proven as the optimal way of processing AND's garbled tables (See, e.g., S. Zahur, M. Rosulek, and D. Evans, “Two halves make a whole,” in Advances in Cryptology—EUROCRYPT 2015, E. Oswald and M. Fischlin, Eds. Berlin, Heidelberg: Springer Berlin Heidelberg, 2015, pp. 220-250 (incorporated herein by reference).). As the Half-Gate is the primary functional unit in a GE, we go through the algorithm below. FIG. 2 illustrates the Garbler Half-Gate algorithm. The Evaluator's process is similar except it uses half the number of AES calls.

The first step is AES key expansion. AES-128 uses a key expansion algorithm to expand an initial 128-bit key into ten unique ones, named “round keys.” During encryption, each of these 128-bit round keys is used in their corresponding AES round. The algorithm uses an S-Box along with rotation and XOR operations to generate each round key. Each round key depends on the previous key, serializing the computation.

The next step is to compute the AES-based hash function of the input labels. Like FreeXOR, the Garbler will also choose a random value R and sets A₁=A₀⊕R as well as B. The Garbler will use the input labels as well as their hashed results to construct the garbled table. To evaluate the Half-Gate, the Evaluator receives the two rows of the garbled table. Then, the Garbler uses the garbled table, inputs labels, and hashes the labels to compute the output. In the end, to reveal a secret output to plaintext, the Garbler and Evaluator decrypt the label by comparing their outputs. The comparison result will be the correct real output of the gate.

### § 3.2.1.1.3.4 Fixed-Key Block Cipher Versus

### Re-Keying

For the Half-Gate, there are four AES called during garbling and two in evaluation, per gate. The fixed-key block cipher (See, e.g., M. Bellare, V. T. Hoang, S. Keelveedhi, and P. Rogaway, “Efficient garbling from a fixed-key blockcipher,” in 2013 IEEE Symposium on Security and Privacy. IEEE, 2013, pp. 478-492 (incorporated herein by reference).) provides a potentially more efficient mechanism for garbling and evaluating non-XOR gates using fixed-key AES, which means one key per AES evaluation per gate. Thus, fixed-key does not require as many key expansions as re-keying and is easier to process. A fixed-key approach is used by prior work on accelerating GCs (See, e.g., the documents: S. U. Hussain and F. Koushanfar, “Fase: Fpga acceleration of secure function evaluation,” in 2019 IEEE 27th Annual International Symposium on Field-Programmable Custom Computing Machines (FCCM), 2019, pp. 280-288 (incorporated herein by reference); S. U. Hussain, B. D. Rouhani, M. Ghasemzadeh, and F. Koushanfar, “Maxelerator: Fpga accelerator for privacy preserving multiply-accumulate (mac) on cloud servers,” 2018 55th ACM/ESDA/IEEE Design Automation Conference (DAC), pp. 1-6, 2018 (incorporated herein by reference).); and E. M. Songhori, S. Zeitouni, G. Dessouky, T. Schneider, A.-R. Sadeghi, and F. Koushanfar, “Garbledcpu: A mips processor for secure computation in hardware,” 2016 53nd ACM/EDAC/IEEE Design Automation Conference (DAC), pp. 1-6, 2016 (incorporated herein by reference).). However, a recent study (See, e.g., the documents: S. Gueron, Y. Lindell, A. Nof, and B. Pinkas, “Fast garbling of circuits under standard assumptions,” in Proceedings of the 22nd ACM SIGSAC Conference on Computer and Communications Security, ser. CCS '15. New York, NY, USA: Association for Computing Machinery, 2015, p. 567-578 (incorporated herein by reference).); and C. Guo, J. Katz, X. Wang, C. Weng, and Y. Yu, “Better concrete security for half-gates garbling (in the multi-instance setting),” in Advances in Cryptology—CRYPTO 2020, D. Micciancio and T. Ristenpart, Eds. Cham: Springer International Publishing, 2020, pp. 793-822 (incorporated herein by reference).) shows that this method reduces Half-Gate security. To maintain the security, HAAC consistent with the present description uses re-keying AES rather than fixed-key AES. Instead of using one single 128-bit key for each AES per gate we generate multiple 128-bit keys for different AESs. The present inventors benchmarked the difference on a CPU and found that re-keying increases the Half-Gate latency by 27.5%.

### § 3.2.1.1.4 Non-Cryptographic

Non-cryptographic techniques for secure computing also exist, specifically trusted execution environments (TEEs) and differential privacy (DP). TEEs are used today, provide confidentiality and control over how data is used (See, e.g., I. Anati, S. Gueron, S. P. Johnson, and V. R. Scarlata, “Innovative technology for cpu based attestation and sealing,” 2013 (incorporated herein by reference).), and tend to be much faster than cryptographic techniques. However, they have been shown to be vulnerable to attacks (See, e.g., J. Van Bulck, M. Minkin, O. Weisse, D. Genkin, B. Kasikci, F. Piessens, M. Silberstein, T. F. Wenisch, Y. Yarom, and R. Strackx, “Foreshadow: Extracting the keys to the intel sgx kingdom with transient out-of-order execution,” in 27th USENIX Security Symposium, 2018 (incorporated herein by reference).). DP can provide strong privacy and security guarantees through statistics. DP is used today to protect computations that aggregate data. Its drawbacks are that applications to direct client-cloud computation are still unclear and security is achieved via adding noise, which can introduce approximations in the computation.

In view of the foregoing, it would be useful to improve hardware such as garbled circuits to moderate known drawbacks such as high computational overheads and/or large data footprints due to the wires and tables.

### § 4. SUMMARY OF THE INVENTION

The challenge(s) of improving hardware such as garbled circuits is/are addressed by designing custom-logic gate hardware units that leverage the parallelism in gate computation. Further, since each GC program is completely determined at compile time, this enables programmable hardware (i.e., instruction set architecture (ISA) support) for executing any GC program with high performance and efficiency to be developed by relying on the compiler to organize all data movement and instruction scheduling. This eliminates the need for the hardware to extract performance from a program, and all costly microarchitectural mechanisms for finding instruction-level parallelism (ILP) and memory-level parallelism (MLP) can be elided as the benefits are realized via software. While the hardware design may be seen as simple, this is intentional as it results in more chip area being devoted to the actual computation rather than supporting logic to extract parallelism and performance.

Example methods for managing a memory for storing operands input to, and output from, hardware operators, are provided. In one case, the example method (1) defines a contiguous region (or range) of address space in the off-chip memory for storing the operands to also be stored on a smaller, on-chip memory, (2) determines whether or not a given operand output from a hardware operator will advance beyond (or otherwise fall outside of) the contiguous region of address space, and (3) responsive to a determination that a given operand output from a hardware operator will advance beyond (or otherwise fall outside of) the contiguous region of address space, adjusts (e.g., slides) the contiguous region of address space in the off-chip memory to define an adjusted contiguous region of address space in the memory such that the adjusted contiguous region of address space in the off-chip memory includes the given operand output from the hardware operator, and such that an older operand(s) in the on-chip memory is overwritten with the given operand output from the hardware operator, whereby both the off-chip memory and the on-chip memory store the given operand output from the hardware operator.

In at least some example implementations of the example method, each of the operands is a wire label, and each of the hardware operators is a gate engine defined by an encrypted truth tables. In at least some such example implementations, the hardware operators define a garbled circuit.

In at least some example implementations of the example method, the contiguous region of address space in the memory includes m partitions (where m is at least two), and the act of adjusting (e.g., sliding) the contiguous region of address space in the off-chip memory to define an adjusted contiguous region of address space in the memory such that the adjusted contiguous region of address space in the off-chip memory includes the given operand output from the hardware operator, and such that an older operand(s) in the on-chip memory is overwritten with the given operand output from the hardware operator, whereby both the off-chip memory and the on-chip memory store the given operand output from the hardware operator (Recall Block 640.) includes adjusting a mapping of partitions between on-chip and off-chip memory so that the m+1 partition stored in the off-chip memory overwrites old operands stored in the on-chip memory. That is, SWW (i.e., the smaller, on-chip memory, which can be accessed faster than the off chip memory), will change its mapping of operands stored from one range to another range of the off-chip memory (“slide”). In example implementations, m is 2, or m is a power of 2.

In at least some example implementations, the act of adjusting the contiguous region of address space in the memory held to define an adjusted contiguous region of address space in the memory such that the adjusted contiguous region of address space in the memory can store the given operand output from the hardware operators may be performed by defining an out-of-range queue data structure storing at least one operand outside the contiguous region (e.g., range) of address space in the memory for storing operands.

In at least some example implementations, the example method further includes defining an out-of-range queue data structure storing at least one operand outside the contiguous region (e.g., range) of address space in the memory for storing operands. In at least some such example implementations, an order of the hardware operations is predetermined, and the at least one operand outside the contiguous region of address space in the memory for storing operands is a plurality of operations queued in the out-of-range queue in an order corresponding to the predetermined order of the hardware operations.

In at least some example implementations, the example method further includes (1) compiling a software program into instructions for execution by the hardware operators, (2) reordering the instructions such that instruction parallelism is improved, wherein the act of reordering randomizes memory addresses of the operands output from each operation, and (3) renaming the operands output from each operation such that their respective output memory addresses (e.g., result addresses) are linearized. In at least some such examples, as a result of the act of renaming, the memory addresses of the operands output from each operation are withing the contiguous region of address space in the memory. In some such example implementations, the act of reordering the instructions includes (1) partitioning the instructions into segments sized as a function of a size of the memory, and (2) reordering the instructions within each of the segments such that instruction parallelism within the segment is improved. In at least some such example implementations, for each of the segments, the act of reordering the instructions may include (1) constructing an operator dependence graph of the instructions within the segment, (2) iterating through nodes of the operator dependence graph, and (3) appending the nodes of the operator dependence graph as they are iterated to generate a new instruction list.

Processors and systems may be provided to perform any of the foregoing methods.

### § 5. BRIEF DESCRIPTION OF THE DRAWINGS

FIG. 1 illustrates GC terminology.

FIG. 2 illustrates Half-Gate computation by a GC Garbler.

FIG. 3 is a block diagram of an example HAAC accelerator consistent with the present description (assuming four GEs and eight SWW banks), with details of a GE.

FIG. 4 illustrates an overview of the flow of an example HAAC compiler consistent with the present description, as well as optimizations.

FIGS. 5A-5F illustrate examples of SWW memory in a manner consistent with the present description.

FIG. 6 is a flow diagram of an example method of memory management for storing operands input to and output from hardware operators, in a manner consistent with the present description.

FIG. 7 is a flow diagram of an example method for adjusting the contiguous region of address space in the memory held to define an adjusted contiguous region of address space in the memory.

FIG. 8 is a flow diagram of an additional step, which may be used in the example method of FIG. 6.

FIG. 9 is a flow diagram of additional steps, which may be used in the example method of FIG. 6.

FIG. 10 is a flow diagram of an example instruction reordering method that may be used in the example method of FIG. 9.

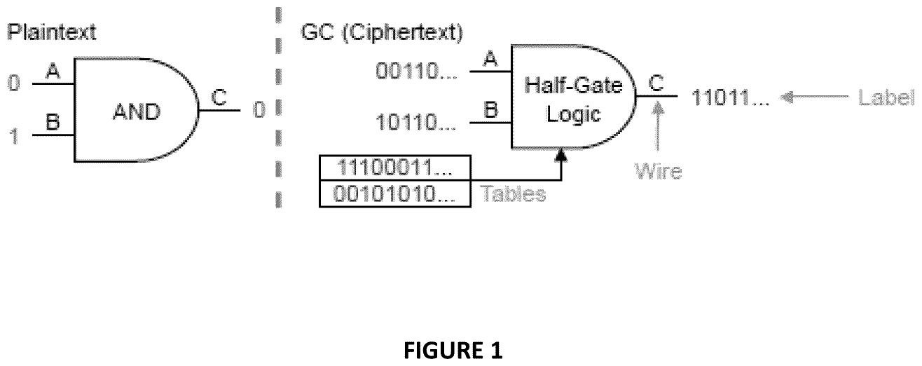

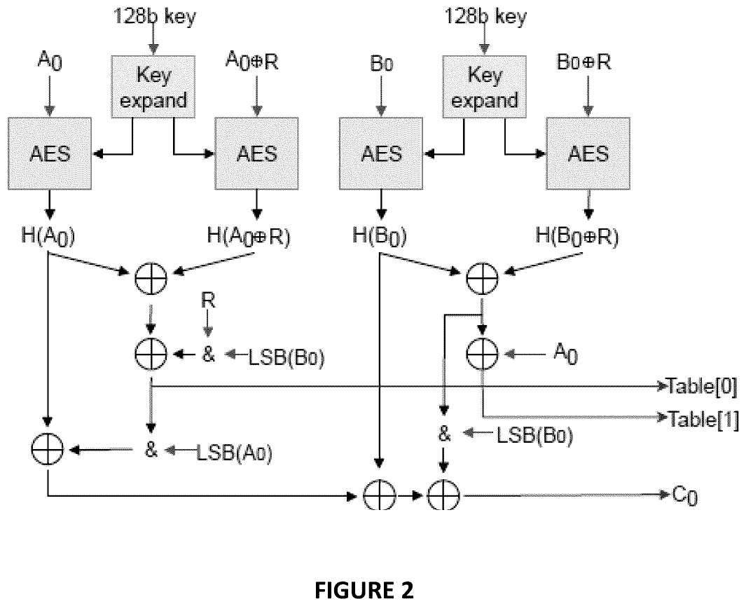

### § 6. DETAILED DESCRIPTION

The present disclosure may involve novel methods, apparatus, message formats, and/or data structures to improve hardware such as garbled circuits to moderate known drawbacks such as high computational overheads and/or large data footprints due to the wires and tables. The following description is presented to enable one skilled in the art to make and use the described embodiments, and is provided in the context of particular applications and their requirements.

Thus, the following description of example embodiments provides illustration and description, but is not intended to be exhaustive or to limit the present disclosure to the precise form disclosed. Various modifications to the disclosed embodiments will be apparent to those skilled in the art, and the general principles set forth below may be applied to other embodiments and applications. For example, although a series of acts may be described with reference to a flow diagram, the order of acts may differ in other implementations when the performance of one act is not dependent on the completion of another act. Further, non-dependent acts may be performed in parallel. No element, act or instruction used in the description should be construed as critical or essential to the present description unless explicitly described as such. Also, as used herein, the article “a” is intended to include one or more items. Where only one item is intended, the term “one” or similar language is used. Thus, the present disclosure is not intended to be limited to the embodiments shown and the inventors regard their invention as any patentable subject matter described.

GCs have two fortuitous properties that enable effective hardware acceleration. First, the core computations, though complex, are highly amenable to hardware implementation. The present inventors show in the '675 provisional, that by designing custom-logic gate hardware units that leverage the parallelism in gate computation, performance can be significantly improved. Second, each GC program is completely determined at compile time. This means all control flow and memory accesses are available at compile time, providing software with a full understanding of a program's execution. This presents a prime opportunity for hardware-software co-design. This enables programmable hardware (i.e., instruction set architecture (ISA) support) for executing any GC program with high performance and efficiency to be developed by relying on the compiler to organize all data movement and instruction scheduling. Reminiscent of very long instruction word (VLIW) instruction set architectures, this eliminates the need for the hardware to extract performance from a program, and all costly microarchitectural mechanisms for finding instruction-level parallelism (ILP) and memory-level parallelism (MLP) can be elided as the benefits are realized via software. While the hardware design may be seen as simple, this is intentional as it results in more chip area being devoted to the actual computation rather than supporting logic to extract parallelism and performance.

Alternative approaches are possible but tend to be overly restrictive or unnecessary. For example, a fixed-logic ASIC approach would constrain functional support for arbitrary programs that GCs provide. Systolic arrays and vectors place constraints on how data is laid out and computation ordered, which can constrain the hardware's ability to process arbitrary programs well. Dataflow would be wasteful as the compiler can handle instruction scheduling and avoid allocating costly associative structures. The present description shows how the properties of GCs can be leveraged for significant performance improvement by striking a balance between the hardware and software.

HAAC, named Half-Gate Accelerator, is a novel co-design approach for accelerating GCs. It includes a compiler, ISA, and hardware accelerator that combine to improve GC performance by well over two orders of magnitude. HAAC significantly improves gate computation by developing gate engines (GEs), which are custom logic units that accelerate the execution of individual gates. GEs provide high performance potential, but the present description describes how to manage all the different data structures (instructions, tables, wires) effectively while keeping the hardware simple and efficient.

One insight by the present inventors is how the compiler, with hardware support, can express the problem as multiple sets of streams. Having complete knowledge of the program, the compiler can leverage the high degrees of ILP to improve intra-GE/inter-GE parallel processing. Then, knowing the precise order and timing of events, the instructions and tables for AND gates can be streamed into each GE using queues.

Handling wires is more difficult as accesses are random with respect to program order. The present description describes two example methods—sliding wire window memory (SWW) and renaming—for optimizing wires. The SWW is a scratchpad memory for storing a contiguous range of wires that increases as the program executes. Renaming is a compiler pass that serializes all output wire addresses following their program ordering. SWW and renaming combine to filter off-chip accesses as recently generated wires are typically reused soon after they are written. SWW and renaming also provides random access to deal with wire accesses over a fixed, adaptive range. The SWW and renaming provide the performance benefits of a cache with the efficiency and determinism of a scratchpad. While the SWW filters out most wire accesses, there will always be some out-of-range (OoR) wire access events. As HAAC implements strictly in-order pipelines, sporadic long-latency DRAM accesses would cause significant performance degradation. A second example wire optimization method described in the present application is to stream in OoR wires. Since the compiler knows when and which wires will be OoR, it can push the wire data on-chip into a OoR wire queue local to each GE.

An important implication of the wire optimizations is that it enables a complete decoupling of the execution unit (GEs) and off-chip accesses, allowing for total overlap by streaming all data.

Example hardware consistent with the present description is described in § 6.1 below. Example compilers consistent with the present description is described in § 6.2 below.

### § 6.1 Example HAAC Hardware

High-performance hardware tailored to the workload's needs can be used to speedup GCs. One goal of HAAC is to increase (e.g., maximize) performance while reducing (e.g., minimizing) hardware complexity and area. To achieve this, HAAC pushes instruction scheduling, data layout and off-chip movement management to the compiler. This section describes the design of example hardware.

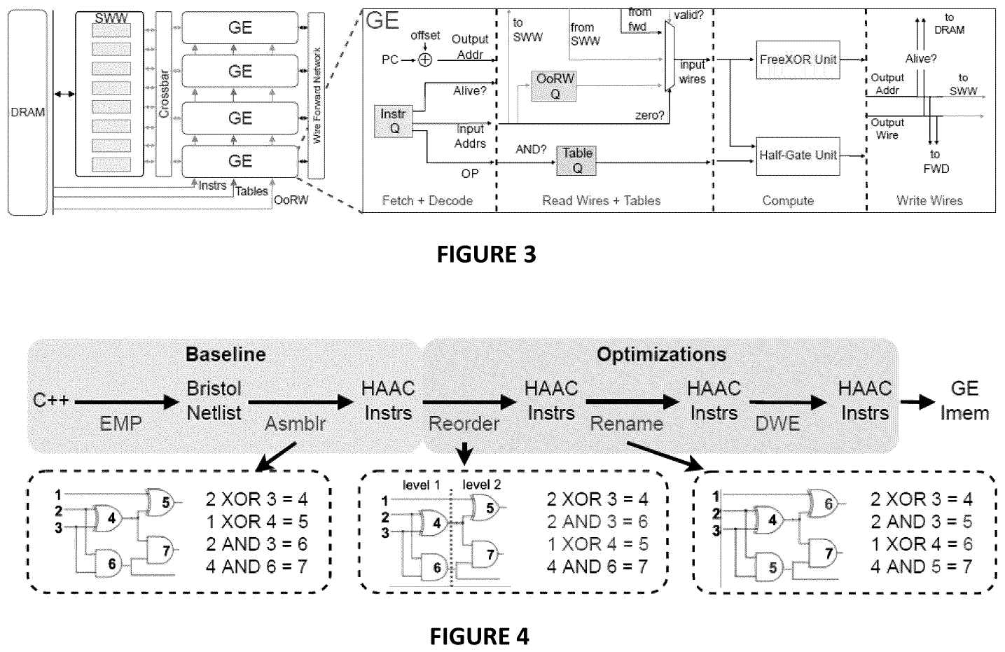

FIG. 3 is a block diagram of an example HAAC accelerator consistent with the present description (assuming four GEs and eight SWW banks), with details of a GE. The left side of FIG. 3 shows an overview of the proposed hardware. Gate engines (GEs) are the computational pipelines used to execute HAAC instructions. The number of GEs can be scaled to provide the desired computational throughput. Each GE contains a private instruction memory (streaming), table memory (streaming), and out-of-range wire memory (streaming). A wire forwarding network handles intra-GE and inter-GE data hazards for fast resolution and sharing across pipelines. The GEs share an on-chip wire memory, the sliding wire window, which each can read and write.

The memory structures (access) and GEs (execute) are controlled independently to allow the overlap of off-chip data movement with execution in a decoupled fashion. From the GEs' perspective, everything needed to process a program is on-chip, and it has no knowledge of off-chip events. The four memory structures are all controlled separately from the GEs using simple controllers configured by the HAAC compiler. The details of how software manages control and creates streams are covered in § 6.2. The hardware and software are tightly entwined. Section 6.1 details the memory subsystem and compute logic that realizes this design philosophy.

### § 6.1.1 Memory Subsystem

HAAC's example on-chip memory subsystem allocates unique structures to each GC data type. Allocating distinct memories provides two benefits. First, this increases parallelism as they can be accessed simultaneously. Second, this improves efficiency as some structures are streaming while others require random access. This subsection describes how the structures are designed to meet the needs of GCs.

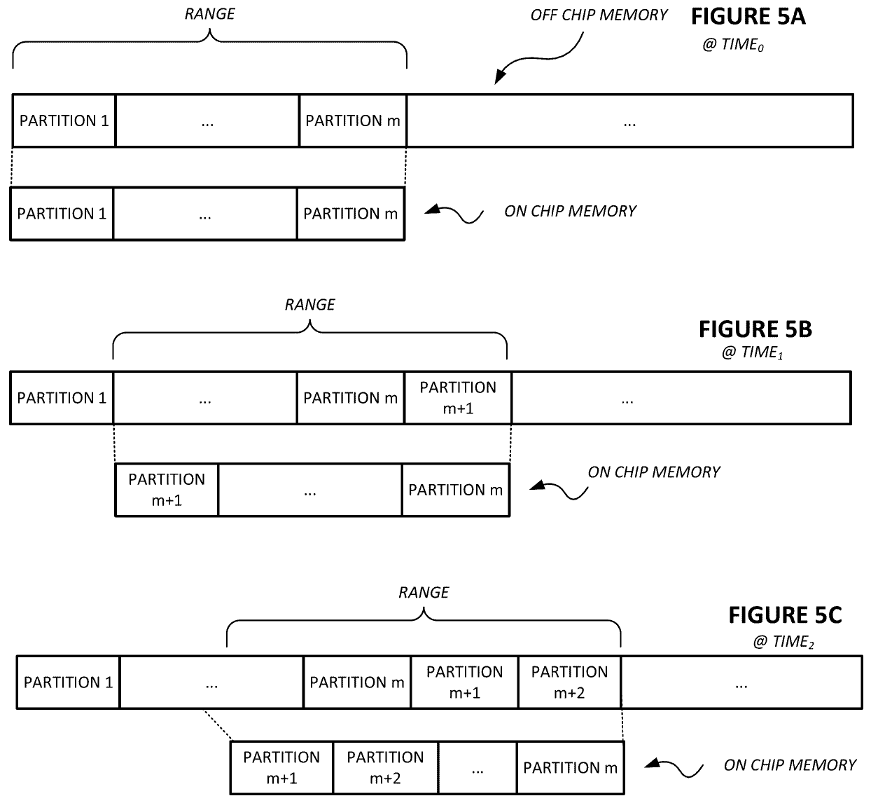

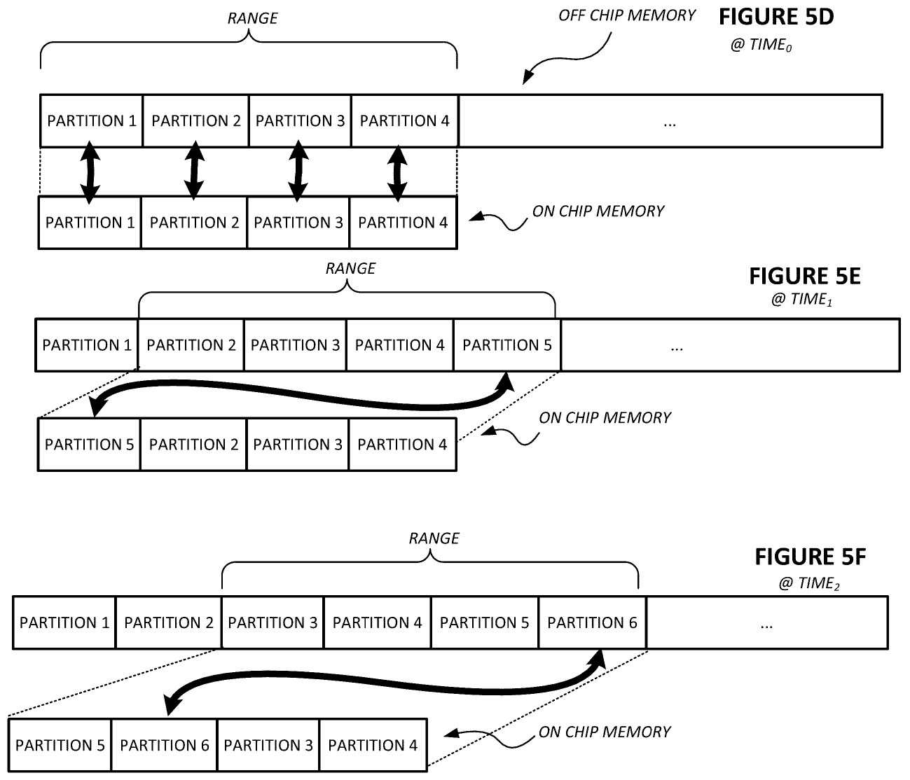

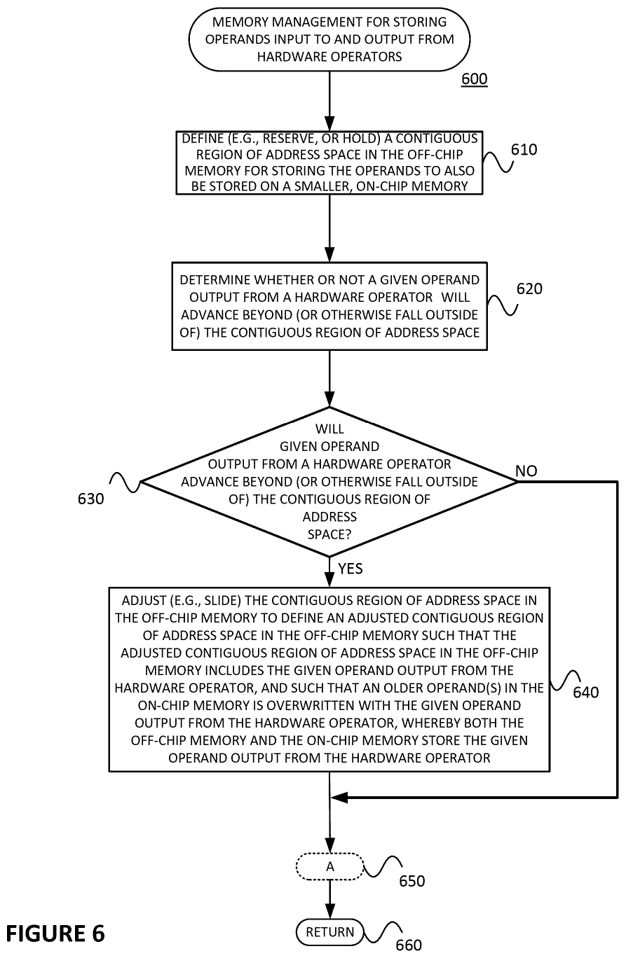

The following describes example methods for managing a memory for storing operands input to, and output from, hardware operators. The example methods are described with reference to FIGS. 5A-8. Referring first to FIGS. 5A and 6, the example method 600 defines (e.g., reserving, or holding) a contiguous region (or range) of address space in the off-chip memory for storing operands that are also to be stored in a smaller, faster, on-chip memory. (FIGS. 5A and 5D, and Block 610) The example method 600 then determines whether or not a given operand output from a hardware operator will advance beyond (or otherwise fall outside of) the contiguous region of address space. (Block 620) Responsive to a determination that a given operand output from a hardware operator will advance beyond (or otherwise fall outside of) the contiguous region of address space (Decision 630=YES), the example method 600 adjusts (e.g., slides) the contiguous region of address space in the off-chip memory to define an adjusted contiguous region of address space in the off-chip memory such that the adjusted contiguous region of address space in the off-chip memory includes the given operand output from the hardware operator, and such that an older operand(s) in the on-chip memory is overwritten with the given operand output from the hardware operator, whereby both the off-chip memory and the on-chip memory store the given operand output from the hardware operator. (FIGS. 5A->5B, 5B->5C, 5D->5E and 5E->5F, and Block 640) If, on the other hand, example method 600 determines that the given operand output from a hardware operator will not advance beyond (or otherwise fall outside of) the contiguous region of address space (Decision 630=NO), the adjustment of block 640 is not made. The example method 600 may then be left. (Return node 660) However, the example method 600 may include further steps, denoted by node A (Node 650), before the method 600 is left (Return node 660).

In at least some example implementations of the example method 600, each of the operands is a wire label, and each of the hardware operators is a gate engine defined by an encrypted truth tables. In at least some such example implementations, the hardware operators define a garbled circuit.

In at least some example implementations of the example method 600, the contiguous region of address space in the memory includes m partitions (where m is at least two), and the act of adjusting (e.g., sliding) the contiguous region of address space in the off-chip memory to define an adjusted contiguous region of address space in the memory such that the adjusted contiguous region of address space in the off-chip memory includes the given operand output by the hardware operator, and such that an older operand(s) in the on-chip memory is overwritten with the given operand output from the hardware operator, whereby both the off-chip memory and the on-chip memory store the given operand output from the hardware operator (Recall Block 640.) includes adjusting a mapping of partitions between on-chip and off-chip memory so that the m+1 partition stored in the off-chip memory overwrites old operands stored in the on-chip memory. That is, SWW (i.e., the smaller, on-chip memory, which can be accessed faster than the off chip memory), will change a mapping of its operands stored from one to the other range of the off-chip memory (“slide”). This is illustrated in FIGS. 5B, 5C, 5E, and 5F. This is repeated, as needed. (See FIGS. 5C and 5F.) In some such examples, m is 2, or m is a power of 2. (See, e.g., FIG. 5D, in which m is 4). FIGS. 5D-5F illustrate an example in which m is 4. Referring to FIGS. 5D and 5E, as an operand output from a hardware operator advances outside of the range (i.e., past the end of partition 4), it is written in partition 5 in both the off-chip memory and the on-chip memory. Given the limited space of the on-chip memory, operands written into partition 5 overwrite those (older operands) that were in partition 1. Similarly, referring to FIGS. 5E and 5F, as an operand output from a hardware operator advances outside of the previously updated range (i.e., past the end of partition 5), it is written in partition 6 in both the off-chip memory and the on-chip memory. Given the limited space of the on-chip memory, operands written into partition 6 overwrite those (older operations) that were in partition 2.

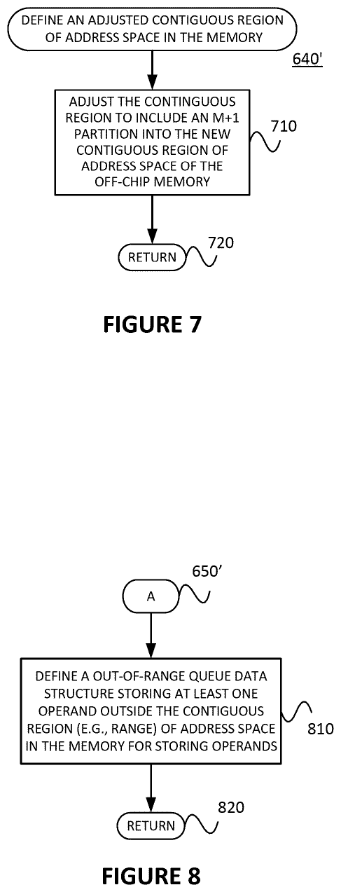

Referring back to block 640, as shown in FIG. 7, in one example implementation 640′, the act of adjusting (e.g., sliding) the contiguous region of address space in the off-chip memory to define an adjusted contiguous region of address space in the off-chip memory such that the adjusted contiguous region of address space in the off-chip memory includes the given operand output from the hardware operator, and such that an older operand(s) in the on-chip memory is overwritten with the given operand output from the hardware operator, whereby both the off-chip memory and the on-chip memory store the given operand output from the hardware operator may be performed by defining an out-of-range queue data structure storing at least one operand outside the contiguous region (e.g., range) of address space in the memory for storing operands. (Block 710)

Referring back to node A (node 650), as shown in FIG. 8, in one example implementation 650′, the example method 600 further includes defining an out-of-range queue data structure storing at least one operand outside the contiguous region (e.g., range) of address space in the memory for storing operands. (Block 810) In at least some such example implementations, an order of the hardware operations is predetermined, and the at least one operand outside the contiguous region of address space in the memory for storing operands is a plurality of operations queued in the out-of-range queue in an order corresponding to the predetermined order of the hardware operations.

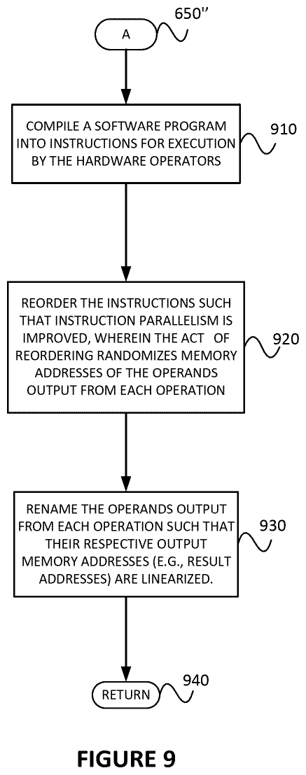

Referring back to node A (node 650), as shown in FIG. 9, in one example implementation 650″, the example method 600 further includes (1) compiling a software program into instructions for execution by the hardware operators (Block 910), (2) reordering the instructions such that instruction parallelism is improved, wherein the act of reordering randomizes memory addresses of the operands output from each operation (Block 920), and (3) renaming the operands output from each operation such that their respective output memory addresses (e.g., result addresses) are linearized (Block 930). In at least some such examples, as a result of the act of renaming, the memory addresses of the operands output from each operation are withing the contiguous region of address space in the memory.

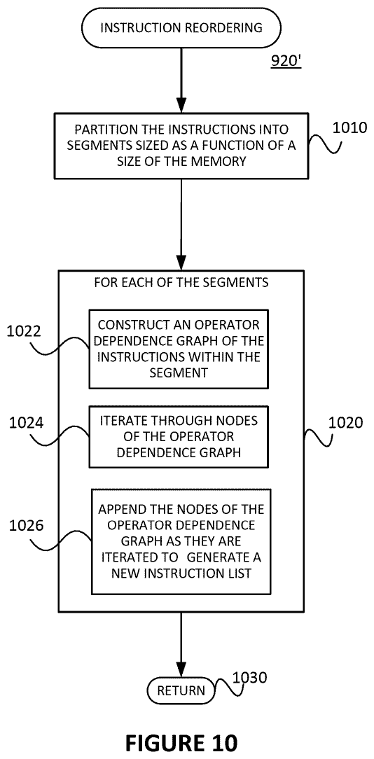

Referring back to block 920 of FIG. 9, as shown in FIG. 10, in some example implementations 920′, the act of reordering the instructions includes (1) partitioning the instructions into segments sized as a function of a size of the memory (Block 1010), and (2) reordering the instructions within each of the segments such that instruction parallelism within the segment is improved (Block 1020). In at least some such implementations, for each of the segments, the act of reordering the instructions (Block 1020) may include (1) constructing an operator dependence graph of the instructions within the segment (Block 1022), (2) iterating through nodes of the operator dependence graph (Block 1024), and (3) appending the nodes of the operator dependence graph as they are iterated to generate a new instruction list (Block 1026).

### § 6.1.1.1 Sliding Window Wire (SWW) Memory

As noted above, “wires” are the inputs and outputs of gates. HAAC stores wires on-chip using a scratchpad memory. A scratchpad provides the random access support needed for input operands and enables HAAC to capture wire reuse across gates within a finite (contiguous) address range. An alternative is to stream all wires to GEs. Streaming would reduce chip area by eliminating the wire SRAM and crossbar. However, streaming would miss significant wire reuse. The present inventors have found that most generated wires are only read by instructions that closely follow.

The wire memory is named the sliding wire window (SWW) to reflect how the address space is managed. To provide random access support without address tagging, the SWW always holds a contiguous region of wire addresses. Assuming the wire memory can hold n−1 wires, the initial range of addresses is [0, n−1]. (Recall, e.g., FIGS. 5A and 5D.) Part of the HAAC co-design is to generate output wires in a sequential address order (See § 6.2.) for renaming.

As the frontier of computed output wires advances past the currently held range, the wire address range the SWW holds is incremented. To keep SWW management simple, in one implementation, it is logically partitioned in half. (That is, the number of partitions m is two.) When an output wire exceeding the SWW range is generated (n exceeding n−1), the SWW address range is assumed to cover a new range by remapping the first half of the space (Recall, e.g., FIGS. 5A and 5B, as well as FIGS. 5D and 5E, assuming m=2.) to the next set of contiguous addresses (from [0, 0.5n] to [n,1.5n]) so that the new range can capture upcoming new wires. In this way, the SWW slides over the entire wire address space tracking output wire addresses. When an input wire is read within the range currently held, it can be accessed directly from the SWW, saving an off-chip bandwidth. The renaming pass ensures that program-wide wire addresses are properly mapped to the physically addressable 0 to n−1 range of the SWW.

In one example embodiment, the SWW is implemented as a collection of single-port SRAM banks that runs twice as fast as logic for high on-chip bandwidth. Each SRAM word stores a wire label and valid bit to indicate whether data is ready to use. The wire memory may be connected to the GEs with a crossbar.

### § 6.1.1.2 Table Memory

Each AND gate (instruction) is associated with a unique table. The Garbler generates tables and the Evaluator consumes them. Within each side, tables are not reused as the output wires. Each gate is executed once, and the order of gates each GE will process at compile time is known. To optimize tables using this understanding tables are streamed from/to each GE. Each time an AND instruction is encountered in an (Evaluator) GE, it pops the next table off the head of the table queue and uses it to compute the AND instruction. The strict, known, ordering of AND gates further simplifies instruction encoding, as AND accesses are implicit and do not require addressing.

### § 6.1.1.3 Instruction Memory

Instructions are streamed through each GE via a GE-local queue. Queues work well for instructions since there is no reuse nor control flow in GC instructions. (Note that GCs do functionally support conditional statements, it is encoded into the GC logic circuits themselves. Thus, once we have the circuit, there is no control flow in a HAAC program.) Therefore, providing random access support would be wasteful as instructions are always accessed in order.

### § 6.1.1.3.1 Instruction Encoding

Each HAAC instruction must specify the gate's operation (2b), two input wire addresses (16b each for 1 MB SWW), and if the output wire will be alive (1b) after current SWW, i.e., needs to be saved to off chip DRAM. That is, if alive, the output wire will be saved (not just SWW but also) to DRAM (because alive indicates that it will be used after current SWW range). Wire output address does not need to be specified as they are generated in order (See renaming in § 6.2 below.), and the addresses can be computed incrementally using the instruction's program position. This advantageously saves encoding the output wire address.

### § 6.1.1.4 Out-of-Range Wires

The SWW can filter most gate input wire accesses and, by design, all wire output writes. However, since the GCs support arbitrary logic, there are usually input wire accesses that exceed the wire range currently held by the SWW. There are two key properties that the example HAAC can leverage to avoid the drawbacks of a standard cache or pull-based design. Since it is known when and to which wire addresses out-of-range (OoR) accesses happen, time and energy searching the SWW needn't be spent (since we know it is not there), nor is it necessary to rely on a pull-based access event, which would introduce high latency to HAAC's in-order pipeline. To optimize for this, a third, GE-local queue (named the out-of-range wire (OoRW) queue) is proposed. The head of this queue will always contain the wire needed by the next instruction that incurs an OoR access, which the compiler can determine. The zero wire address is reserved to indicate OoR and that the wire should be read from the queue, not the SWW. If both operands are OoR, the first operand is handled first. By preemptively pushing all OoR accesses to the OoRW queue, all long-latency access events can be eliminated, and in HAAC all data is now streaming on-off chip. Pushing OoR wire reads to the queue helps to enable complete decoupling between data movement and execution in HAAC hardware. This is enabled by the co-design approach described in the present application.

### § 6.1.2 GE Pipeline

Referring back to FIG. 3, the right side of FIG. 3 illustrates that the GE pipeline constitutes a simple frontend for fetching and decoding instructions, stages to read wires and tables, execution units for Half-Gate (AND) and FreeXOR (XOR), write-back, and forwarding logic. GEs are deeply pipelined to run at high frequency and overlap instructions, leveraging workload ILP.

### § 6.1.2.1 Frontend

Each GE may be provided with a scratchpad for HAAC instructions, which are fetched sequentially. There is no control flow needed in GCs, and decoupled units manage data movement following a compiler determined order. This significantly simplifies fetch and decode logic as no control flow nor memory instructions are needed. The fetch and decode stages fetch the next instruction off the instruction memory queue, determine which of the three instruction types (AND, XOR, nop) it is, compute the output wire address wire address and forward addresses to proceeding stages.

### § 6.1.2.2 Read Wires and Table

Wire addresses are used to index the SWW. Wire reads may be split across three pipeline stages, and a crossbar may be used to interface SWW banks with GEs. It takes one cycle to get the address to the bank, one to read a bank, and one to get data from the bank to the GE. Each stored wire may include a valid bit to indicate the value has been computed. If a wire valid bit is false, it is known that the wire label is currently being computed in a GE and its value will be retrieved via the forwarding logic. These data hazards introduce stalls and the reorder optimization attempts to minimize them. (See, e.g., § 6.2.) When a wire address of zero is decoded, the wire is accessed from the head of the OoR wire queue rather than the SWW. If the operator is an AND, a table is retrieved from the head of the table queue in parallel to the input wire accesses. Table queues are local to GEs and can be accessed in a single cycle.

### § 6.1.2.3 Compute Units

The heart of the GE is the execution pipeline. To maximize performance, the present inventors developed custom logic units for both the Half-Gate and FreeXOR computations. In GCs, a party can be either a Garbler or Evaluator, needing support for only one. Therefore, distinct units are designed for the Garbler and the Evaluator to maximize performance while the rest of the pipeline is shared. Each unit was designed using High-Level Synthesis (HLS) with the Efficient MultiParty (EMP) open source toolkit implementations as a reference and to validate correctness.

### § 6.1.2.3.1 Half-Gate Unit

Directly running EMP code through HLS did not perform well and significant optimization effort was put in to develop a high-performance unit. The main issues stemmed from the key expansion and AES modules. Both modules have multiple rounds of processing the same functions, and rounds must be processed sequentially. Many of the arrays in the design (e.g., key storage for AES) were initially implemented using SRAMs, which are more area efficient than flip-flops but only provide a single data access per cycle. Further, much of the allocated hardware was re-used across different modules. For example, the S-BOX lookup table is implemented as a single ROM. Since there was one instance of the S-BOX this only allows a single round of key expansion or a single round of AES to take place at any given time. (Note that these small SRAMs are embedded in the pipeline and distinct from wire/table SRAMs; they are accessed implicitly.) The reuse of these structures is area efficient, but limits parallelism and the ability to pipeline the long-latency computation. This resulted in low throughput and clock frequency.

To improve performance, parts of the example design reused across rounds (i.e., S-BOX, MixColumns, and XOR arrays) were replicated with the inline HLS pragma to alleviate resource contention. Next, all SRAM instances within the unit were flattened to registers. This enabled direct access to different parts of the array by allowing reads and writes to take place to different indices at the same time, enabling multiple data accesses per clock cycle. False data dependencies were resolved with code re-writing. Loops may be (e.g., manually) unrolled, and parallel logic to overlap computation HLS could not find may be explicitly instantiated. The remaining loops may then be unrolled with pragmas. Our example optimized design is fully pipelined, and capable of accepting a new input every cycle to maximize throughput. The Garbler and Evaluator GE have 21 and 18 stages pipeline, respectively. No changes affect the correctness, which was verified against EMP by the present inventors.

### § 6.1.2.3.2 FreeXOR Pipeline

The FreeXOR unit is much simpler than the Half-Gate. An example FreeXOR may be implemented using an array of XORs. A single cycle is needed to compute FreeXOR due to the simplicity and parallel nature of the computation. XOR hardware exists in the AES logic used in the Half-Gate unit. However, they are not shared so that FreeXORs is allowed to run in parallel. The benefit is that XORs can complete in one cycle and immediately resolve dependencies rather than incurring the full Half-Gate pipeline latency.

### § 6.1.2.3.3 Write and Forward Wires

Once the computation finishes, the output wire label is written back to SWW. If the alive bit is set, it is also sent out to DRAM. Writing the SWW takes two cycles: a first cycle to move the data over the crossbar; and a second cycle to write the SRAM bank's cells.

GEs also support forwarding. When there is a wire address match between a completing instruction and one in the frontend, the writeback stage forwards the wire's values. When multiple GEs are used, the forwarding logic extends across GEs and the overall area is a function of the number of GEs used. In practice, the logic is not expensive. For a 16 GE design, it takes 0.018 mm². An alternative approach would be to encode the data dependence information in the ISA. However, this further complicates the compiler, frontend, and increases the instruction size. As the forwarding logic is simple and inexpensive, it is used in the example HAAC.

### § 6.2 Example HAAC Compiler

This section describes an example HAAC compiler. The compiler has two jobs: (1) to optimize programs for high-performance on HAAC hardware; and (2) generate the streams for the queues. The overall compiler flow is described in § 6.2.1 below. Then detail three optimizations for improving performance are described in § 6.2.2.

### § 6.2.1 Overview

FIG. 4 illustrates an overview of the flow of an example HAAC compiler consistent with the present description, as well as optimizations. The software workflow is shown in the top of FIG. 4 and proceeds as follows. First, the user implements a C++ program into the EMP Toolkit (See, e.g., X. Wang, A. J. Malozemoff, and J. Katz, “EMP-toolkit: Efficient MultiParty computation toolkit,” (incorporated herein by reference).). The framework is widely used and provides high-level programming support. EMP analyzes programs and outputs a netlist in Bristol format. (See, e.g., S. Tillich and N. Smart, “Circuits of basic functions suitable for mpc and fhe,” 2016 (incorporated herein by reference).) These netlists are converted to HAAC instructions using an assembler. The output from the assembler is a baseline HAAC program to which optimizations are compared. Optimization details are described in § 6.2.2 below, and are applied in order. Reordering (RO) first optimizes instruction schedules, renaming linearizes gate output wire addresses, and dead wire elimination (DWE) elides redundant writes to off-chip memory.

The final step of the compiler is to generate queue streams. All queues are GE-local, and the first step is to determine which instructions are processed in each GE. This is done by mapping instructions from the program to non-stalled GEs each cycle in our simulator, saving the order, and replaying it in hardware. Doing prevents any load imbalance that would occur if a round-robin approach were to be used, and eliminates the need for expensive super-scalar like hardware structures. Next, knowing the order of instructions enables the compiler to determine the garbled table order by inspecting each GE instruction stream. Lastly, the order of OoR wire accesses is determined. This is done by comparing all instruction input wires against the range of wires currently held in the SWW. Once the OoR wires are determined, they can be pushed to the OoR wire queue. Each time an OoR wire is encountered, the GE will obtain OoR wire from the queue instead of addressing the SWW. During this pass, the input wire operands with OoR wires can be replaced with zero.

### § 6.2.2 Optimizations

As just described above, baseline HAAC programs are built directly from EMP by converting a list of gates into HAAC instructions. However, these tend to perform poorly as the netlist does not consider HAAC's hardware, leaving potential performance improvements unrealized. The next three sub-sections describe three optimizations for better instruction scheduling: reordering (See § 6.2.2.1.), improved on-chip reuse (renaming) (See § 6.2.2.2.), and fewer writes to off-chip memory (dead wire elimination) (See § 6.2.2.3.).

§ 6.2.2.1 Exploiting ILP with Reordering

GC programs generally have high ILP, but parallelism is lost in the baseline program as instructions are scheduled following a depth-first traversal of the circuit (i.e., in tight producer-consumer relationships minimizing the distance between dependent gates). A depth-first traversal can save off-chip traffic as wires are reused across neighboring instructions. This, however, can reduce parallelism. The inventors found, empirically, that this results in a significant amount of stalls in GEs as they are in-order and must wait for the data to resolve. Performance can be improved by scheduling HAAC instructions with more distance between dependencies.

### § 6.2.2.1.1 Full Reorder

To maximize instruction independence, HAAC programs are first ordered according to their ILP level-order (breadth-first) in the circuit. To do this, a gate dependence or level graph representation of the entire HAAC program ILP is constructed. Next, each graph level, one node (instruction) at a time, is iterated through, appending traversed nodes to a new instruction list. Since all instructions within a level are independent, this approach generates programs with very high instruction parallelism, and the GEs rarely stall. A full reordering works well for resolving data hazards, but it can increase DRAM pressure due to less wire reuse in the SWW. If a level of the circuit contains too many gates and their output wires exceed the size of the SWW, these wires must be stored to DRAM. That is, although benefiting compute parallelism, strictly prioritizing instruction parallelism can result in missed opportunities for input wire reuse.

### § 6.2.2.1.2 Segment Reorder

To better balance wire reuse and improve instruction parallelism, a segmented reorder schedule is described. Here, rather than computing the ILP graph for the entire program, the baseline program is first partitioned into segments. Then, instructions within each segment are reordered. The segment size is set to match the size of the SWW. First, this means segments are rather large (e.g., 65536 instructions for 1 MB SWW) and the ILP within segments is usually sufficient to avoid stalls. Second, by restricting a segment to the SWW range, much of the wire locality is preserved, as instructions that share wires remain close to each other in program order. In general, segment reorder provides better compute performance than the baseline program and tends to capture more wire reuse than full reorder.

§ 6.2.2.2 Linearizing Output Wires with Renaming

In the baseline netlist, wire addresses are assigned in an increasing order. Reordering randomizes a program's wire accesses relative to their program position, breaking this ordering. The SWW provides on-chip buffering support for a contiguous portion of the wire address space, as this is much more efficient than random access support. If the reordered instructions were used directly, the random wire access tends to go out of the on-chip wire range. To effectively utilize the SWW, the output wires of each (post-reordered) instruction is renamed to follow the program order. This provides two advantages. First, it concentrates a program's wire accesses to the range currently supported by the on-chip wire memory. Linearizing the output wire addresses to match the instruction order optimizes for wires being generated, stored locally on-chip, and being reused. Second, linearizing outputs saves instruction encoding space as the output wire address is (e.g., always) incremental.

§ 6.2.2.3 Saving Write Bandwidth with Dead Wire Elimination (DWE)

Not all computed wires need to be written back to off-chip memory. Each generated wire is used a finite number of times and in many cases wires computed within a SWW range are also only ever used within that range. The HAAC compiler flags wires that need to be written back by setting the alive bit in the instruction. This may be implemented by statically checking whether an output wire is ever used past its current SWW boundary. The optimization was found to be highly effective--on average, only 18.2% wires need to be written back after the optimization.

### § 6.3 Performance

The performance of the example hardware-software co-design of the example HAAC implementation was evaluated. The detailed methodology used for that evaluation, as well as detailed results of that evaluation, are discussed in the '675 provisional, some of which are not repeated here. Briefly stated, an example an example implementation of HAAC was evaluated using VIP-bench to demonstrate speedup and highlight the effectiveness of the approach. Assuming a 16 GE accelerator with a 2 MB SWW and DDR4 (HBM2), the example implementation of HAAC provides an average speedup of 757× (3780×) in 5.74 mm².

### § 6.3.1 Methodology

This section describes how an example implementation(s) of HAAC was evaluated. CPU performance was measured on an Intel Core i7-10700K running at 3.80 GHz. The EMP Toolkit (See, e.g., X. Wang, A. J. Malozemoff, and J. Katz, “EMP-toolkit: Efficient MultiParty computation toolkit,” (incorporated herein by reference).) was used as the software framework, which leverages AES-NI (See, e.g., K. Akdemir, M. Dixon, W. Feghali, P. Fay, V. Gopal, J. Guilford, E. Ozturk, G. Wolrich, and R. Zohar, “Breakthrough aes performance with intel aes new instructions,” White paper, June, vol. 12, p. 217, 2010 (incorporated herein by reference).) for high performance.

The present inventors developed a cycle-accurate simulator to evaluate the example HAAC implementation(s) and explore design tradeoffs. The simulator can be broken into two parts: the GE and memory. The GEs are modeled after our hardware implementations of both the Garbler and Evaluator logic described above. The example HAAC implementation(s) uses multiple clock domains, the GEs run at 1 GHz and the memories run at 2 GHz. The example HAAC implementation(s) was evaluated using two types of DRAM: DDR4-4400 (See, e.g., A. Nukada, “Performance optimization of all reduce operation for multi-gpu systems,” in 2021 IEEE International Conference on Big Data (Big Data). IEEE, 2021, pp. 3107-3112 (incorporated herein by reference).) at 35.2 GB/s and one HBM2 PHY at 512 GB/s bandwidth, as reported previously (See, e.g., the documents: J. Choquette, W. Gandhi, O. Giroux, N. Stam, and R. Krashinsky, “Nvidia a100 tensor core gpu: Performance and innovation,” IEEE Micro, vol. 41, no. 2, pp. 29-35, 2021 (incorporated herein by reference); and NVIDIA, “Nvidia dgx station a100 system architecture,” 2021 (incorporated herein by reference).). The simulator was verified to be functionally correct and handled stalls by precisely tracking all data movement through the hardware.

The example HAAC implementation(s) was evaluated using benchmarks from VIP-Bench (See, e.g., L. Biernacki, M. Z. Demissie, K. B. Workneh, G. B. Namomsa, P. Gebremedhin, F. A. Andargie, B. Reagen, and T. Austin, “Vip-bench: A benchmark suite for evaluating privacy-enhanced computation frameworks,” in 2021 International Symposium on Secure and Private Execution Environment Design (SEED), 2021, pp. 139-149 (incorporated herein by reference).), see Table I of the '675 provisional. To evaluate the performance of the example HAAC implementation(s) and consider relevant problems, either use the original data sizes or scaled-up input sizes were used to better stress the hardware and off-chip behavior as some are too small. The size of Dot Product was increased to two 128 elements 32-bit integer vector, Matrix Multiplication to 8×8 integer matrices, Hamming Distance to 40960-bit length, and ReLU to be evaluated 2048 times. Related work does not use VIP-Bench, as it was released after the relevant papers were published. Workloads reported in prior work are much smaller than VIP, and the '675 provisional only reported their performance for comparison. For example, the 8-bit Millionaire benchmark has only 33 gates, the smallest VIP-Bench workload has 68 k.

Vivado HLS 2018.3 (See, e.g., X. Inc., “Vivado design suite user guide: Ug973,” 2020 (incorporated herein by reference).) was used to implement the Half-Gate unit. Hardware was synthesized without FPGA IP as Verilog. The forwarding network, crossbar, and pipeline stages were hand-implemented in Verilog using Vivado Design Suite 2018.3. The design was functionally verified against EMP. Verilog designs were synthesized using Cadence Genus 18.1 and TSMC 22 nm with a frequency target of 1 GHz. The synthesized netlist was placed and routed using Cadence Innovus 18.1 (See, e.g., M. Dunn, “Innovus implementation system claims up to 10× turnaround time reduction,” Ic Design Synthesis Soc (incorporated herein by reference).). The layout was designed to have a utilization of 70% before place-and-route; power and area numbers were extracted after timing was met. SRAM power and area numbers are from CACTI 7.0 3DD (See, e.g., R. Balasubramonian, A. Kahng, N. Muralimanohar, A. Shafiee, and V. Srinivas, “Cacti 7: New tools for interconnect exploration in innovative off-chip memories,” ACM Transactions on Architecture and Code Optimization, vol. 14, pp. 1-25, 06 2017 (incorporated herein by reference).) the 22 nm technology node. To match prior work on high-performance hardware, memory and standard cell based logic structures were scaled from 22 nm to 16 nm. Using the scaling factors provided by the foundry (See, e.g., the documents: Nanotechnology Products Database, “Tsmc 20 nm technology.” (incorporated herein by reference); Nanotechnology Products Database, “Tsmc 28 nm technology.” (incorporated herein by reference).); and TSMC, “16/12 nm technology.” Available: https://www.tsmc.com/english/dedicatedFoundry/technology/logic/l 16 12 nm (incorporated herein by reference).), the area was scaled by a factor of 0.48× and power by a factor of 0.34×. Delays were scaled by a factor of 0.53×.

### § 6.3.2 Evaluation

In this section, the example HAAC implementation(s) is evaluated using the simulator and benchmarks described above. The performance of the example HAAC implementation(s), the strength of the compiler optimizations, and effectiveness of off-chip data movement reduction techniques, are discussed.

### § 6.3.2.1 Evaluation of Compiler Optimizations

The efficacy of the HAAC compiler is shown below. This experiment assumes a HAAC accelerator 16 GEs, a 2 MB SWW, and DDR4. FIG. 5 of the '675 provisional shows speedup results relative to the original EMP program running on CPU. For each benchmark, green bars indicate the HAAC's speedup using EMP-derived baseline instruction schedules. Blue bars indicate the performance of executing the same program after running HAAC's full reordering and renaming optimizations.

Starting with the original netlist bars (green), we make two observations. First, the results show that even with a baseline program, the example HAAC implementation(s) obtained good results, with an average speedup of 107×. This demonstrates the effectiveness of the GE design over running the programs on a CPU. Next, after the compiler fully reorders the original netlist, an additional average speedup of 3.04× over the baseline was obtained. Across all benchmarks, it was found that the maximum reorder speedup was 6.81× for the Mersenne benchmark. The ReLU benchmark incurs a slowdown with full reordering. Table I of the '675 provisional shows ReLU circuits have only two dependence levels, which means the original netlist has already captured significant parallelism. The full reordering hardly provides additional optimization, but increases the burden to the off-chip memory because it computes 2048 independent ReLUs, which is extremely parallel and reflective of real-world workloads. Thus, full reordering did not improve compute for ReLU while sacrificing on-chip wire reuse, hurting performance. This was overcome with segmented reordering. Disregarding ReLU, the average full reordering speedup increases to 4.25×. Reordered programs are so fast that they reach the bandwidth limits of DDR4.

### § 6.3.2.2 Evaluation of Off-Chip Memory Traffic Optimizations

Dead Wire Elimination (DWE) was used to reduce pressure on bandwidth. Its performance benefits are discussed. Table I of the '675 provisional shows that by adding the alive bit to the wire, an average of 81.8% wires can be saved from being stored back to off-chip memory, freeing up significant bandwidth. The red bar in FIG. 5 of the '675 provisional indicates the performance of the compiler with DWE. By reducing the wires that need to be stored off-chip memory, an average of 2.15× was achieved. (This is more speedup than full reordering alone.) Hamming distance shows the most speedup, 3.34×, which matches expectations from Table I of the '675 provisional. The performance gain by DWE also indicates that the reordered programs reach the memory bound. Thus, DWE can provide speedup over the full reordering. DWE is an efficient way to improve performance as most programs are memory-bound after reordering.

### § 6.3.2.2 Evaluation of Segment Reorder

As alluded to above, full reordering improves parallelism but can spread the wire accesses over too wide a range within a limited instruction window. This prevents the SWW from capturing on-chip wire reuse. Segment reordering solves this by restricting reordering to partitions of the program, preserving wire reuse while realizing most of the parallelism benefits of full program reordering. FIG. 6 of the '675 provisional shows the performance of different orderings using two representative benchmarks: MatMul and BubbleSort. The bars show the compute (red) and off-chip wire traffic (blue) time for the baseline, segment, and fully reordered program. Each ordering was evaluated using three SWW sizes (0.5, 1, and 2 MB). The segment size was set to match the SWW size, which was found to perform best. A HAAC accelerator with 16 GEs and DDR4 was considered.

It is clear that increasing the SWW reduces wire traffic time (blue). A larger SWW covers a wider wire address range and increases on-chip wire reuse, improving DWE as fewer wires are saved to DRAM. Increasing SWW size does not change the compute time for the baseline or fully reordered programs. Since the segment size equals the SWW size, segment compute time can improve as more parallelism is found over the larger window.

Segment reordering is highly effective for MatMult. As FIG. 6 of the '675 provisional shows, MatMul is compute bound in the baseline. Full reordering improves compute performance by 48.8×, unlocking the parallelism in the instructions. However, it does so at the expense of wire memory traffic, erasing on-chip reuse and increasing traffic time by 2.09× for a 1 MB SWW. This behavior is analyzed with reference to the upper plots of FIG. 7 of the '675 provisional. The x-axis is the gate in program order and the y-axis shows the wire addresses of each gate/instruction. Blue dots indicate wire accesses SWW and red show out-of-range (OoR). Observe that when using a full reordering with MatMul, many wires are OoR, causing poor SWW utilization and increasing DRAM pressure. The baseline MatMult program needs fewer DRAM reads as EMP generates netlists in a depth-first order (i.e., executing dependent gates first) instead of breadth-first order as in full reordering. A depth-first traversal benefits SWW but restricts instruction parallelism, throttling GEs performance. Segment reordering balances compute parallelism and memory bandwidth. FIG. 7 of the '675 provisional shows three bands of wire reads in the segment plot that are similar to the band at the bottom of the full reorder plot. However, segment reordering is able to capture the accesses in the SWW whereas the full reordering band causes many OoR accesses.

Segment reordering is not always optimal. One case is BubbSt, as shown in FIG. 6 of the '675 provisional. Here, segment reordering does not benefit wire traffic compared to full reordering, and has a higher compute time due to limited instruction parallelism. This behavior is understood from FIG. 7 of the '675 provisional. The wire access pattern of BubbSt is different from MatMult. BubbSt has fewer average gates per level, and after a full reordering, our SWW memory is still enough to store the temporary wires even though the program follows a complete breadth-first traversal. This can be seen in the lower right plot in FIG. 7 of the '675 provisional, where a large percentage of wire read in SWW, rather than OoR, is found. Therefore, segment reordering does not improve the wire traffic for BubbSt, but it does sacrifice parallelism. In practice, since performance is deterministic, one can simply run both programs (segmented and full program), and deploy the better one.

### § 6.3.3 Evaluation of Parallel Ge Execution and Speedup Over Software

The scaling of performance with the number of gate engines (GEs) and how much speedup the example HAAC implementation(s) provides compared to a CPU baseline, were analyzed. Figure of the '675 provisional shows the speedup results relative to CPU performance. The performance was evaluated by scaling the GEs from 1 to 16 and using a 2 MB SWW. How SWW banks and GEs interact was evaluated empirically. It was found that 4 banks per GE works well to minimize banking while avoiding contention, and this ratio was used in the evaluation. Two types of DRAM are assumed: DDR4 to fairly compare with our CPU; and HBM2 to understand how well HAAC benefits from technologies. All benchmarks were optimized using full reordering to maximize ILP and stress the memory system, Optimal compiler results below.

It was found that in most cases, performance scales well when increasing the number of GEs initially, but designs can saturate DDR4 bandwidth and become memory bound. This can be seen when GE speedup bars plateau. With HBM2, the performance continues to scale across the range of GEs considered. When a red bar is greater than its corresponding blue bar, HAAC is constrained by DDR4's memory bandwidth, and HBM2 can help continue to scale performance. Assuming HBM2, it was found that the maximum speedup increase from one to sixteen engines with HBM2 is 15.5× (for MatMult), while the geomean speedup is 14.0× for the Evaluator HAAC (the Garbler is nearly identical). Referring back to Table I of the '675 provisional, observe that all the benchmarks have significant degrees of ILP. This shows that HAAC successfully leverages, achieving near ideal speedup from 1 to 16 GEs.

Regardless of which design is ultimately used, it was found that the example HAAC implementation(s) provides substantial benefits over a pure software implementation. Using only a single GE, a HAAC accelerator provides a maximum speedup of 760× (ReLU) and a geomean of 269×. When going to the highly-parallel 16 GE design, a maximum full reorder speedup of 2729× (Merse) and geomean speedup of 658× was observed, using DDR4 as the CPU running software.

### § 6.3.4 Evaluation of Area and Power

FIG. 9 of the '675 provisional shows the area and power numbers of a 16 GE design with a 2 MB SWW and 64 banks. The design assumed 64 KB SRAMs for table, instruction, and OoRW streams. The majority of chip area goes to the GE, specifically the Half-Gate unit. Note that as FreeXOR and the forwarding network are so small, they were included in the “Other” category. The total area for the larger Garbler design (including the on chip memory and crossbars) is 5.74 mm² in 16 nm. The total power dissipation for this design is 14.1 W, which includes the off-chip DRAM memory access power. (See, e.g., A. Montgomerie-Corcoran and C.-S. Bouganis, “Pommel: Exploring off-chip memory energy & power consumption in convolutional neural network accelerators,” in 2021 24th Euromicro Conference on Digital System Design (DSD). IEEE, 2021, pp. 442-448 (incorporated herein by reference).) The on-chip memory system dissipated a high percentage of the total power because it ran at twice the frequency of the GE's clock. This and the high switching rate of the cryptographic circuits contributed to the high power dissipation.

### § 6.3.5 Evaluation Compared to Plaintext

Understanding speedup relative to a software implementations helps show the merit of a design. However, an important measure of performance in PPC is how well it performs relative to non-encrypted plaintext. FIG. 10 of the '675 provisional compares the runtimes of HAAC (using both DDR4 and HBM2) assuming the best reordering scheme for each benchmark compared to native, plaintext C++ and EMP (see: CPU GC). The results are encouraging.

Compared to CPU-run GCs, the example HAAC implementation(s) with HBM2 had a geomean speedup of 3780× across benchmarks, while the geomean slowdown compared to plaintext was 32×. HAAC eliminates much of the performance overheads of GC performance as the plaintext making the slowdown much more tolerable. This unlocks the potential for private and secure computing as HAAC accelerators can be deployed in many different settings from mobile to the cloud. Due to the increased data sizes and more work-per-function, PPCs cannot match plaintext performance at iso-area/power; there is simply more work to do per function. However, additional compiler optimizations, leveraging higher levels of parallelism (e.g., multiple HAAC chips), and processing-in-memory (PIM, for extreme bandwidth) should help close the remaining performance gap.

### § 6.3.6 Evaluation Compared to Related Work

Finally, the example HAAC implementation(s) was compared against prior work. Note that all prior works use a less secure formulation of GCs and only accelerate garbling (See, e.g., C. Guo, J. Katz, X. Wang, C. Weng, and Y. Yu, “Better concrete security for half-gates garbling (in the multi-instance setting),” in Advances in Cryptology—CRYPTO 2020, D. Micciancio and T. Ristenpart, Eds. Cham: Springer International Publishing, 2020, pp. 793-822 (incorporated herein by reference).). Nonetheless, reported results from the related works papers were used to show how well the example HAAC implementation(s) performs. (If prior work was modified to support the more computationally expensive and secure garbled circuits, the present inventors would their results to improve.) The comparison was challenging. For example, ASICs can have a greater frequency, but FPGAs (as used in prior work) have large dies, e.g., 84 mm² (See, e.g., C. Ravishankar, D. Gaitonde, and T. Bauer, “Placement strategies for 2.5 d fpga fabric architectures,” in 2018 28th International Conference on Field Programmable Logic and Applications (FPL). IEEE, 2018, pp. 16-164 (incorporated herein by reference).). Some prior works use SHA-1 instead of AES and assume no re-keying, which is simpler. Moreover, most prior works use small benchmarks that do not stress off-chip bandwidth, which is an important advantage provided by HAAC. Nonetheless, a comparison is provided to acknowledge prior work and to provide readers with an understanding of what has already been done.

Table II of the '675 provisional shows how the example HAAC implementation(s) compares favorably to related work. Performance improvement is especially noticeable for large workloads such as AES and matrix multiplication. FASE (See, e.g., S. U. Hussain and F. Koushanfar, “Fase: Fpga acceleration of secure function evaluation,” in 2019 IEEE 27th Annual International Symposium on Field-Programmable Custom Computing Machines (FCCM), 2019, pp. 280-288 (incorporated herein by reference).) is a generic FPGA garbled circuit accelerator that uses a deep pipelined architecture. MAXelerator (See, e.g., (See, e.g., S. U. Hussain, B. D. Rouhani, M. Ghasemzadeh, and F. Koushanfar, “Maxelerator: Fpga accelerator for privacy preserving multiply-accumulate (mac) on cloud servers,” 2018 55th ACM/ESDA/IEEE Design Automation Conference (DAC), pp. 1-6, 2018 (incorporated herein by reference).) is a systolic-array-like garbled circuits accelerator that only performs multiply-accumulate operations. FPGA Overlay (See, e.g., X. Fang, S. Ioannidis, and M. Leeser, “Secure function evaluation using an fpga overlay architecture,” ser. FPGA '17. New York, NY, USA: Association for Computing Machinery, 2017, p. 257-266 (incorporated herein by reference).) proposes a FPGA accelerator with a cluster of custom logic implementing AND and XOR gates based on SHA-1. Most GC frameworks now use AES for security rather than the less secure SHA-1. Benchmarks used in prior work are much smaller than VIP-Bench. They do not even incur or need to optimize off-chip data movement, while we discuss a more comprehensive design and point out the challenges. As for smaller circuits like Million-8, our speedup is limited in comparison to other work such as FASE (See, e.g., S. U. Hussain and F. Koushanfar, “Fase: Fpga acceleration of secure function evaluation,” in 2019 IEEE 27th Annual International Symposium on Field-Programmable Custom Computing Machines (FCCM), 2019, pp. 280-288 (incorporated herein by reference).) because the benchmark has only 33 instructions and there is no room for optimization.

Others have ported GCs to run on GPUs (See, e.g., the documents: T. K. Frederiksen, T. P. Jakobsen, and J. B. Nielsen, “Faster maliciously secure two-party computation using the gpu,” in International Conference on Security and Cryptography for Networks. Springer, 2014, pp. 358-379 (incorporated herein by reference); N. Husted, S. Myers, A. Shelat, and P. Grubbs, “Gpu and cpu parallelization of honest-but-curious secure two-party computation,” in Proceedings of the 29th Annual Computer Security Applications Conference, ser. ACSAC '13. New York, NY, USA: Association for Computing Machinery, 2013, p. 169-178 (incorporated herein by reference); and S. Pu and J.-C. Liu, “Computing privacy-preserving edit distance and smith-waterman problems on the gpu architecture,” Cryptology ePrint Archive, 2013 (incorporated herein by reference).). While the performance is much better than a CPU, they are still much slower than the example HAAC implementation(s). One implementation shows a

GPU can garble an average of 75 million gates per second (See, e.g., N. Husted, S. Myers, A. Shelat, and P. Grubbs, “Gpu and cpu parallelization of honest-but-curious secure two-party computation,” in Proceedings of the 29th Annual Computer Security Applications Conference, ser. ACSAC '13. New York, NY, USA: Association for Computing Machinery, 2013, p. 169-178 (incorporated herein by reference).), while the example HAAC implementation(s) can garble 8.7 billion gates per second, the power and area of the GPU compared to HAAC is also more than 10× and 70× (See, e.g., M. Burtscher, I. Zecena, and Z. Zong, “Measuring gpu power with the k20 built-in sensor,” in Proceedings of Workshop on General Purpose Processing Using GPUs, 2014, pp. 28-36 (incorporated herein by reference).), respectively. One of HAAC's benefits comes from the use of custom data paths and a memory system optimized for wires and tables, which is substantially different from a GPU.

Yao's canonical paper on garbled circuits was published in 1986 (See, e.g., A. C.-C. Yao, “How to generate and exchange secrets,” in 27th Annual Symposium on Foundations of Computer Science (sfcs 1986), 1986, pp. 162-167 (incorporated herein by reference).). Since then, many algorithmic optimizations have been developed to reduce the computational complexity and storage overheads of GCs. GCs have recently received an increase in attention due to privacy and security concerns

Researchers have steadily developed new optimizations to improve GC efficiency. The most commonly used optimizations include Point-and-Permute (See, e.g., D. Beaver, S. Micali, and P. Rogaway, “The round complexity of secure protocols (extended abstract),” 1990 (incorporated herein by reference).), Row Reduction (See, e.g., the documents: M. Naor, B. Pinkas, and R. Sumner, “Privacy preserving auctions and mechanism design,” in Proceedings of the 1st ACM Conference on Electronic Commerce, ser. EC '99. New York, NY, USA: Association for Computing Machinery, 1999, p. 129-139 (incorporated herein by reference).); and B. Pinkas, T. Schneider, N. P. Smart, and S. C. Williams, “Secure two-party computation is practical,” in Advances in Cryptology—ASIACRYPT 2009, M. Matsui, Ed. Berlin, Heidelberg: Springer Berlin Heidelberg, 2009, pp. 250-267 (incorporated herein by reference).), FreeXOR (See, e.g., V. Kolesnikov and T. Schneider, “Improved garbled circuit: Free xor gates and applications,” vol. 7, 07 2008, pp. 486-498 (incorporated herein by reference).), and Half-Gate (See, e.g., S. Zahur, M. Rosulek, and D. Evans, “Two halves make a whole,” in Advances in Cryptology—EUROCRYPT 2015, E. Oswald and M. Fischlin, Eds. Berlin, Heidelberg: Springer Berlin Heidelberg, 2015, pp. 220-250 (incorporated herein by reference).). Point-and-Permute reduces table rows the Evaluator decrypts but increases table size. Row reduction reduces the number of table rows and is a predecessor to the Half-Gate optimization used in some implementations of HAAC. Several software implementations of GCs now exist (See, e.g., the documents: Y. Huang, D. Evans, J. Katz, and L. Malka, “Faster secure two-party computation using garbled circuits,” vol. 8, 08 2011, pp. 35-35 (incorporated herein by reference); C. Liu, X. S. Wang, K. Nayak, Y. Huang, and E. Shi, “Oblivm: A programming framework for secure computation,” in 2015 IEEE Symposium on Security and Privacy, 2015, pp. 359-376 (incorporated herein by reference); B. Mood, D. Gupta, H. Carter, K. Butler, and P. Traynor, “Frigate: A validated, extensible, and efficient compiler and interpreter for secure computation,” 03 2016 (incorporated herein by reference); and X. Wang, A. J. Malozemoff, and J. Katz, “EMP-toolkit: Efficient MultiParty computation toolkit,” https://github.com/emp-toolkit, 2016 (incorporated herein by reference).). They largely offer similar utilities but differ in interfaces and programming language.

Prior work has looked at accelerating GCs with FPGAs (See, e.g., the documents: X. Fang, S. Ioannidis, and M. Leeser, “Secure function evaluation using an fpga overlay architecture,” ser. FPGA '17. New York, NY, USA: Association for Computing Machinery, 2017, p. 257-266 (incorporated herein by reference); K. Huang, M. Gungor, X. Fang, S. Ioannidis, and M. Leeser, “Garbled circuits in the cloud using fpga enabled nodes,” in 2019 IEEE High Performance Extreme Computing Conference (HPEC), 2019, pp. 1-6 (incorporated herein by reference); S. U. Hussain, B. D. Rouhani, M. Ghasemzadeh, and F. Koushanfar, “Maxelerator: Fpga accelerator for privacy preserving multiply-accumulate (mac) on cloud servers,” 2018 55th ACM/ESDA/IEEE Design Automation Conference (DAC), pp. 1-6, 2018 (incorporated herein by reference); and E. M. Songhori, S. Zeitouni, G. Dessouky, T. Schneider, A.-R. Sadeghi, and F. Koushanfar, “Garbledcpu: A mips processor for secure computation in hardware,” 2016 53nd ACM/EDAC/IEEE Design Automation Conference (DAC), pp. 1-6, 2016 (incorporated herein by reference).), as well as GPUs (See, e.g., the documents: N. Husted, S. Myers, A. Shelat, and P. Grubbs, “Gpu and cpu parallelization of honest-but-curious secure two-party computation,” in Proceedings of the 29th Annual Computer Security Applications Conference, ser. ACSAC '13. New York, NY, USA: Association for Computing Machinery, 2013, p. 169-178 (incorporated herein by reference); and S. Pu, P. Duan, and J.-C. S. Liu, “Fastplay-a parallelization model and implementation of smc on cuda based gpu cluster architecture,” IACR Cryptol. ePrint Arch., vol. 2011, p. 97, 2011 (incorporated herein by reference).). To the best of our knowledge HAAC is the first ASIC design of the GC accelerator. As discussed earlier, prior works have two shortcomings in that they support a less secure formulation of GCs, which are cheaper to compute. HAAC outperforms all prior accelerator and GPU work, as shown in section VI of the '675 provisional.

Most work to date has focused on accelerating HE. HE also incurs extremely high overheads, and recent work has made significant advances in mitigating these overheads for integer schemes (See, e.g., the documents: A. Feldmann, N. Samardzic, A. Krastev, S. Devadas, R. Dreslinski, K. Eldefrawy, N. Genise, C. Peikert, and D. Sanchez, “F1: A fast and programmable accelerator for fully homomorphic encryption (extended version),” 2021 (incorporated herein by reference).); S. Kim, J. Kim, M. Kim, W. Jung, M. Rhu, J. Kim, and J. H. Ahn, “Bts: An accelerator for bootstrappable fully homomorphic encryption,” 12 2021 (incorporated herein by reference).); B. Reagen, W. Choi, Y. Ko, V. Lee, G.-Y. Wei, H.-H. S. Lee, and D. Brooks, “Cheetah: Optimizing and accelerating homomorphic encryption for private inference,” 2020 (incorporated herein by reference); M. S. Riazi, K. Laine, B. Pelton, and W. Dai, “Heax: An architecture for computing on encrypted data,” in Proceedings of the Twenty-Fifth International Conference on Architectural Support for Programming Languages and Operating Systems, 2020 (incorporated herein by reference); and N. Samardzic, A. Feldmann, A. Krastev, N. Manohar, N. Genise, S. Devadas, K. Eldefrawy, C. Peikert, and D. Sanchez, “Craterlake: a hardware accelerator for efficient unbounded computation on encrypted data,” 06 2022, pp. 173-187 (incorporated herein by reference).). Others have looked at accelerating binary HE. However, binary HE evaluation is tens to hundreds of times slower than GCs (See, e.g., the documents: H. Hsiao, V. Lee, B. Reagen, and A. Alaghi, “Homomorphically encrypted computation using stochastic encodings,” arXiv preprint arXiv:2203.02547, 2022 (incorporated herein by reference).); and L. Jiang, Q. Lou, and N. Joshi, “Matcha: A fast and energy-efficient accelerator for fully homomorphic encryption over the torus,” arXiv preprint arXiv:2202.08814, 2022 (incorporated herein by reference).). For example, computing a single TFHE addition takes 3.51s (See, e.g., T. Morshed, M. M. Al Aziz, and N. Mohammed, “Cpu and gpu accelerated fully homomorphic encryption,” in 2020 IEEE International Symposium on Hardware Oriented Security and Trust (HOST). IEEE, 2020, pp. 142-153 (incorporated herein by reference).) while GCs take 12.1 us. Comparing accelerated solutions, the example HAAC implementation(s) can evaluate GC gates with a maximum latency of 18 ns while TFHE ASICs take 0.18 ms/gate (See, e.g., L. Jiang, Q. Lou, and N. Joshi, “Matcha: A fast and energy-efficient accelerator for fully homomorphic encryption over the torus,” arXiv preprint arXiv:2202.08814, 2022 (incorporated herein by reference).). Some have also looked at running HE kernels on GPUs (See, e.g., the documents: W. Dai, “Cuda-accelerated fully homomorphic encryption library,” https://github.com/vernamlab/cuFHE (incorporated herein by reference); and B. Reagen, W. Choi, Y. Ko, V. Lee, G.-Y. Wei, H.-H. S. Lee, and D. Brooks, “Cheetah: Optimizing and accelerating homomorphic encryption for private inference,” 2020 (incorporated herein by reference).). They typically report two orders of magnitude speedup over a CPU, which is impressive but short of mitigating the 5-6 order of slowdown.

### § 6.4 Alternatives, Refinements, and/or Extensions

Our invention is not limited to the specific embodiments described. Rather, the present inventors consider their invention to include any patentable subject matter described in this application. For example, certain parts of the system described above can be used in other systems. As a specific example, the sliding wire window (SWW) memory and/or its use and/or management can be applied to privacy preserving techniques other than garbled circuits (GCs). As another specific example, the sliding wire window (SWW) memory and/or its use and/or management can be applied to logic other than Half-Gate (AND) and FreeXOR (XOR). Other variations are possible and contemplated.

Any of the foregoing methods may be performed by a processor (e.g., general purpose, integrated circuit, ASIC, etc.). A system comprising: (a) a plurality of hardware operators; (b) a memory device for storing operands input to and output from the plurality of hardware operators; and (c) a processor (e.g., general purpose, integrated circuit, ASIC, etc.) configured to manage the memory device a method for managing a memory for storing operands input to and output from hardware operators. Program instructions may be stored on a non-transitory computer-readable storage medium.

### § 6.5 Conclusions

The present description presents a hardware-software co-design approach to accelerating garbled circuits, named HAAC. We show how many of the complexities typical of high-performance hardware can be avoided by pushing all instruction scheduling, data layout, and data movement management to the compiler. The hardware can then devote chip resources to structures needed to perform the computation. This allows our design to be both area efficient and high-performance. Our specific contributions are the development of gate engine (GE) hardware units used to speedup GC gate computations, four unique memory structures tailored to the needs of each GC data structure, and a compiler that produces high-performance mappings of high-level code onto the hardware to realize its performance potential. HAAC improves GC performance over a CPU by 757× using only 5.74 mm² of chip area.

GCs have two fortuitous properties that enable effective hardware acceleration. First, the core computations, though complex, are highly amenable to hardware implementation. The present inventors have found that by designing custom-logic gate hardware units that leverage the parallelism in gate computation, performance can be significantly improved. Second, each GC program is completely determined at compile time. This means all control flow and memory accesses are available at compile time, providing software with a full understanding of a program's execution. This presents a prime opportunity for hardware-software co-design. Programmable hardware (i.e., ISA support) can be developed for executing any GC program with high performance and efficiency by relying on the compiler to organize all data movement and instruction scheduling. Reminiscent of VLIW, this eliminates the need for the hardware to extract performance from a program, and all costly microarchitectural mechanisms for finding ILP and MLP can be elided as the benefits are realized via software. While the hardware design may be seen as simple, this is intentional as it results in more chip area being devoted to the actual computation rather than supporting logic to extract parallelism and performance. Alternative approaches are possible but tend to be overly restrictive or unnecessary. For example: A fixed-logic ASIC approach would constrain functional support for arbitrary programs that GCs provide. Systolic arrays and vectors place constraints on how data is laid out and computation ordered, which can constrain the hardware's ability to process arbitrary programs well. Dataflow would be wasteful as the compiler can handle instruction scheduling and avoid allocating costly associative structures. The present description shows how the properties of GCs can be leveraged for significant performance improvement by striking a balance between the hardware and software.

HAAC, named Half-Gate Accelerator, is a novel co-design approach for accelerating GCs. It includes a compiler, ISA, and hardware accelerator that combine to improve GC performance by well over two orders of magnitude. HAAC significantly improves gate computation by developing gate engines (GEs), which are custom logic units that accelerate the execution of individual gates. GEs provide high performance potential, but more performance improvements are obtained by managing all the different data structures (instructions, tables, wires) effectively while keeping the hardware simple and efficient.

One key insight is how the compiler, with hardware support, can express the problem as multiple sets of streams. Having complete knowledge of the program, the compiler can leverage the high degrees of ILP to improve intra-/inter-GE parallel processing. Then, knowing the precise order and timing of events, the instructions and tables for AND gates can be streamed into each GE using queues. Handling wires is more difficult as accesses are random with respect to program order. Two methods for optimizing wires were described. The present inventors developed the sliding wire window memory, or SWW, (in HW) and wire renaming (in SW). The SWW is a scratchpad memory for storing a contiguous range of wires that increases as the program executes. Renaming is a compiler pass that serializes all output wire addresses following their program ordering. SWW and renaming combine to filter off-chip accesses as recently generated wires are typically reused soon after they are written, it also provides random access to deal with wire accesses over a fixed, adaptive range. The SWW and renaming provide the performance benefits of a cache with the efficiency and determinism of a scratchpad. While the SWW filters out most wire accesses, there will always be some out-of-range (OoR) wire access events. As HAAC implements strictly in-order pipelines, sporadic long-latency DRAM accesses would cause significant performance degradation. Our second wire optimization method is to stream in OoR wires. Since the compiler knows when and which wires will be OoR, it can push the wire data on-chip into a OoR wire queue local to each GE.

An important implication of the wire optimizations is that it enables a complete decoupling of the execution unit (GEs) and off-chip accesses, allowing for total overlap by streaming all data. The present application makes the following two contributions. First, the present application describes a novel hardware design tailored to the needs of GCs, including gate engines (GEs) to accelerate gate computations, queues (instruction, table, and OoR wire) and scratchpads (SWW) for each unique GC data structure. The hardware is general purpose and supports an ISA. Second, the present application also describes an optimizing compiler to manage high-performance parallel instruction scheduling (re-ordering), effective data layout and memory accesses (re-naming), and reduce unnecessary off-chip communication (dead-wire elimination).

What is claimed is:

1. A method for managing an off-chip memory and an on-chip memory for storing operands input to and output from hardware operators, the method comprising:
a) defining a contiguous region of address space in the off-chip memory for storing the operands to also be stored on the on-chip memory; and
b) responsive to a determination that a given operand output from a hardware operator will advance beyond, or otherwise fall outside of, the contiguous region of address space, adjusting the contiguous region of address space in the off-chip memory to define an adjusted contiguous region of address space in the off-chip memory such that the adjusted contiguous region of address space in the off-chip memory includes the given operand output from the hardware operator, and such that at least one older operand in the on-chip memory is overwritten with the given operand output from the hardware operator, whereby both the off-chip memory and the on-chip memory store the given operand output from the hardware operator.

2. The method of claim 1, wherein each of the operands is a wire label, and wherein each of the hardware operators is a gate engine defined by an encrypted truth tables.

3. The method of claim 2, wherein the hardware operators define a garbled circuit.

4. The method of claim 1, wherein the contiguous region of address space in the memory includes m partitions, where m is at least two, and
wherein the act of adjusting the contiguous region of address space in the off-chip memory to define an adjusted contiguous region of address space in the off-chip memory such that the adjusted contiguous region of address space in the off-chip memory includes the given operand output from the hardware operator, and such that at least one older operand in the on-chip memory is overwritten with the given operand output from the hardware operator, whereby both the off-chip memory and the on-chip memory store the given operand output from the hardware operator includes
adjusting the contiguous region to include an m+1 partition into the new contiguous region of the address space of the off-chip memory.

5. The method of claim 4, wherein m is 2.

6. The method of claim 4, wherein m is a power of 2.

7. The method of claim 1, further comprising:
defining an out-of-range queue data structure storing at least one operand outside the contiguous region of address space in the memory for storing operands.

8. The method of claim 7 wherein an order of the hardware operations is predetermined, and wherein the at least one operand outside the contiguous region of address space in the memory for storing operands is a plurality of operations queued in the out-of-range queue in an order corresponding to the predetermined order of the hardware operations.

9. The method of claim 1 further comprising:
compiling a software program into instructions for execution by the hardware operators;
reordering the instructions such that instruction parallelism is improved, wherein the act of reordering randomizes memory addresses of the operands output from each operation; and
renaming the operands output from each operation such that their respective output memory addresses are linearized.

10. The method of claim 9 wherein, as a result of the act of renaming, the memory addresses of the operands output from each operation are within the contiguous region of address space in the memory.

11. The method of claim 9 wherein, the act of reordering the instructions includes
partitioning the instructions into segments sized as a function of a size of the memory, and
reordering the instructions within each of the segments such that instruction parallelism within the segment is improved.

12. The method of claim 9 wherein, the act of reordering the instructions includes
partitioning the instructions into segments sized as a function of a size of the memory, and
for each of the segments,
1) constructing an operator dependence graph of the instructions within the segment,
2) iterating through nodes of the operator dependence graph, and
3) appending the nodes of the operator dependence graph as they are iterated to generate a new instruction list.

13. A processor configured to perform a method for managing a memory for storing operands input to and output from hardware operators, the method comprising:
a) defining a contiguous region of address space in the memory for storing the operands; and
b) responsive to a determination that a given operand output from a hardware operator will advance beyond, or otherwise fall outside of, the contiguous region of address space, adjusting the contiguous region of address space in the off-chip memory to define an adjusted contiguous region of address space in the off-chip memory such that the adjusted contiguous region of address space in the off-chip memory includes the given operand output from the hardware operator, and such that at least one older operand in the on-chip memory is overwritten with the given operand output from the hardware operator, whereby both the off-chip memory and the on-chip memory store the given operand output from the hardware operator.

14. The processor of claim 13, wherein each of the operands is a wire label, and wherein each of the hardware operators is a gate engine defined by an encrypted truth tables.

15. The processor of claim 14, wherein the hardware operators define a garbled circuit.

16. A system comprising:
a) a plurality of hardware operators;
b) a memory device for storing operands input to and output from the plurality of hardware operators; and
c) a processor configured to manage the memory device a method for managing a memory for storing operands input to and output from hardware operators, the method comprising:
1) defining a contiguous region of address space in the memory for storing the operands; and
2) responsive to a determination that a given operand output from a hardware operator will advance beyond, or otherwise fall outside of, the contiguous region of address space, adjusting the contiguous region of address space in the off-chip memory to define an adjusted contiguous region of address space in the off-chip memory such that the adjusted contiguous region of address space in the off-chip memory includes the given operand output from the hardware operator, and such that at least one older operand in the on-chip memory is overwritten with the given operand output from the hardware operator, whereby both the off-chip memory and the on-chip memory store the given operand output from the hardware operator.

17. The system of claim 16, wherein each of the operands is a wire label, and wherein each of the hardware operators is a gate engine defined by an encrypted truth tables.

18. The system of claim 16, wherein the contiguous region of address space in the memory includes m partitions, where m is at least two, and
wherein the act of adjusting the contiguous region of address space in the off-chip memory to define an adjusted contiguous region of address space in the off-chip memory such that the adjusted contiguous region of address space in the off-chip memory includes the given operand output from the hardware operator, and such that at least one older operand in the on-chip memory is overwritten with the given operand output from the hardware operator, whereby both the off-chip memory and the on-chip memory store the given operand output from the hardware operator includes
adjusting the contiguous region to include an m+1 partition into the new contiguous region of the address space of the off-chip memory.

19. The system of claim 16, wherein the method further includes:
compiling a software program into instructions for execution by the hardware operators;
reordering the instructions such that instruction parallelism is improved, wherein the act of reordering randomizes memory addresses of the operands output from each operation; and
renaming the operands output from each operation such that their respective output memory addresses are linearized.

20. The system of claim 19 wherein, as a result of the act of renaming, the memory addresses of the operands output from each operation are within the contiguous region of address space in the memory, and
wherein, the act of reordering the instructions includes
A) partitioning the instructions into segments sized as a function of a size of the memory, and
B) either (i) reordering the instructions within each of the segments such that instruction parallelism within the segment is improved, or (ii) for each of the segments,
constructing an operator dependence graph of the instructions within the segment,
iterating through nodes of the operator dependence graph, and
appending the nodes of the operator dependence graph as they are iterated to generate a new instruction list.
